(19) United States
(12) Patent Application Publication
(10) Pub. No.: US 2026/0038592 A1
(43) Pub. Date: Feb. 5, 2026

(54) AUTO CALIBRATED READ WITH WORD LINE LINEAR-RAMP AND EFFICIENT PROGRAM VERIFICATION

(71) Applicant: Micron Technology, Inc., Boise, ID (US)

(72) Inventor: Tomoharu Tanaka, Yokohama (JP)

(73) Assignee: Micron Technology, Inc., Boise, ID (US)

(21) Appl. No.: 19/280,029

(22) Filed: Jul. 24, 2025

Related U.S. Application Data
(60) Provisional application No. 63/677,366, filed on Jul. 30, 2024.

(51) Int. Cl. G11C 16/08; G11C 16/04; G11C 16/34

(52) U.S. Cl. CPC G11C 16/08; G11C 16/0483; G11C 16/3459

(57) ABSTRACT

Methods, systems, and devices for techniques for performing a read operation for memory cells are disclosed herein. A word line voltage level is ramped at a first rate of change. Memory cell activation outputs are detected from a subset of the memory cells based on ramping the word line voltage level at the first rate of change. Word line read levels are calibrated for the memory cells based on the detected memory cell activation outputs. The word line voltage level is ramped at a second rate of change, and data stored in the memory cells activated is read when the word line voltage level ramped at the second rate of change reaches the calibrated word line read levels. A reset program verify operation is not applied to memory cells corresponding to at least one stage of the word line based on previously applied programming pulses or program verify operations.

### CROSS-REFERENCE TO RELATED APPLICATION

This application claims priority to U.S. Provisional Application No. 63/677,366, filed on Jul. 30, 2025, entitled “AUTO CALIBRATED READ WITH WORD LINE LINEAR-RAMP AND EFFICIENT PROGRAM VERIFICATION,” the content of which is incorporated by reference in its entirety for all purposes.

### TECHNICAL FIELD

This disclosure relates to one or more systems for memory, including techniques for implementing an auto calibrated read operation and efficient program verification in an array of memory cells.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic ‘1’ or a logic ‘0’. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIGS. 1A and 1B illustrate an example of a host system and a memory system that support techniques for an auto calibrated read operation and efficient program verification for a memory cell in accordance with examples as disclosed herein.

FIG. 1C is a block diagram of a memory device in communication with a memory system controller of a memory system, in accordance with examples as disclosed herein.

FIGS. 2A-2C are illustrative schematics of portions of an array of memory calls in a memory device, in accordance with examples as disclosed herein.

FIG. 2D illustrates an example of a memory device including multiple blocks of memory cells in accordance with examples as disclosed herein.

FIG. 3 is a block diagram of an example apparatus for implementing one or more systems and for performing one or more processes described herein, in accordance with examples as disclosed herein.

FIGS. 4A-4B show a side view of a portion of the three-dimensional structure of a memory device including a structure of memory cell string having a pillar in accordance with examples as disclosed herein.

FIG. 5 is a block diagram of a memory device in which an auto calibrated read operation and an efficient program verification operation can be implemented in accordance with examples as disclosed herein.

FIG. 6 illustrates a flowchart showing a process that supports techniques for an auto calibrated read operation in an array of memory cells in accordance with examples as disclosed herein.

FIG. 7 is a graph showing different curves that represent a comparison of word line waveforms during example read/program operations in accordance with examples as disclosed herein.

FIG. 8 is a graph showing different curves that represent a first rate of change of the word line voltage level. memory cell activation outputs, and a threshold voltage distribution histogram for an array of memory cells in accordance with examples as disclosed herein.

FIG. 9 illustrates an example apparatus for obtaining a threshold voltage distribution in an array of memory cells in accordance with examples as disclosed herein.

FIG. 10 is a graph showing different curves that represent a first rate of change of the word line voltage level. memory cell activation outputs, a threshold voltage distribution histogram, and a second rate of change of the word line voltage level for an auto calibrated read operation in an array of memory cells in accordance with examples as disclosed herein.

FIG. 11 is another graph showing different curves that represent a first rate of change of the word line voltage level, memory cell activation outputs, a threshold voltage distribution histogram, and a second rate of change of the word line voltage level for an auto calibrated read operation in an array of memory cells in accordance with examples as disclosed herein.

FIG. 12 illustrates a flowchart showing a process that supports techniques for efficient program verification in an array of memory cells in accordance with examples as disclosed herein.

FIG. 13 is a graph showing different curves that represent a program pulse word line voltage, a CFBIT (counter fail bit) output, and a threshold voltage distribution histogram for an array of memory cells in which an efficient program verification is performed in accordance with examples as disclosed herein.

FIG. 14 is a graph showing different curves that represent a program pulse word line voltage, a CFBIT output, and a threshold voltage distribution histogram for an array of memory cells in which efficient program verification is performed in accordance with examples as disclosed herein.

FIG. 15 is a graph showing different curves that represent a program pulse word line voltage. a CFBIT output, and a threshold voltage distribution histogram for an array of memory cells in which efficient program verification is performed in accordance with examples as disclosed herein.

FIG. 16 is a graph showing a program algorithm for efficient program verification in an array of memory cells in accordance with examples as disclosed herein.

### DETAILED DESCRIPTION

Memory cells can be connected to a word line, and a word line driver (e.g., an N-bit counter) can be connected to the word line to ramp a voltage level of the word line. A plurality of page buffers can be connected to respective ones of the memory cells such that, for ramped sensing of the word line, digital progressive values can be generated by the word line driver and fed into the plurality of page buffers. The digital progressive values can be converted into an analog ramp (e.g., by a digital to analog converter connected to the word line driver) and applied to the word line for sensing data stored in the memory cells (e.g., a read operation) and/or verifying that a word line program operation is successful (i.e., program verification) at each ramp step.

In a typical read operation for a NAND memory device, a word line driver can cause a selected word line to linearly ramp, e.g., from −1V to 6V, while each of the page buffers enable strobe signals to detect if a threshold voltage, Vₜ, of a corresponding memory cell is higher than a word line voltage at the given time when the strobe signal occurs. If the word line voltage is higher than the threshold voltage, Vₜ, of the memory cell, the page buffer detects a logical ‘1’. If the word line voltage is lower than the threshold voltage, Vₜ, of the memory cell, the page buffer detects a logical ‘0’. The page buffer may use a sense amplifier for such a detection. The number of strobe signals that need to be enabled by each page buffer depends on the read algorithm being implemented. For example, a quad-level memory cell requires a page buffer to enable fifteen strobes to read each of the four bits.

Replacement-gate (RG) NAND memory is a type of NAND memory device that is subject to various charge loss mechanisms. For example, the amount of charge loss in an RG NAND memory device can depend on the number of program/erase (P/E) cycles, operation temperature, read/program disturb, and/or program threshold voltage, Vₜ, distribution changes over time.

To mitigate the effects of charge loss, an optimum set of read levels on a word line can minimize the number of error bits that occur in a read operation. Therefore, it can be advantageous to first calibrate a set of read levels for a word line before initiating a read operation, and then carry out the read operation using the set of calibrated read levels. However, a typical read level calibration can significantly increase the latency of a read operation due to the requirement that the read level calibration be executed prior to the execution of the read operation.

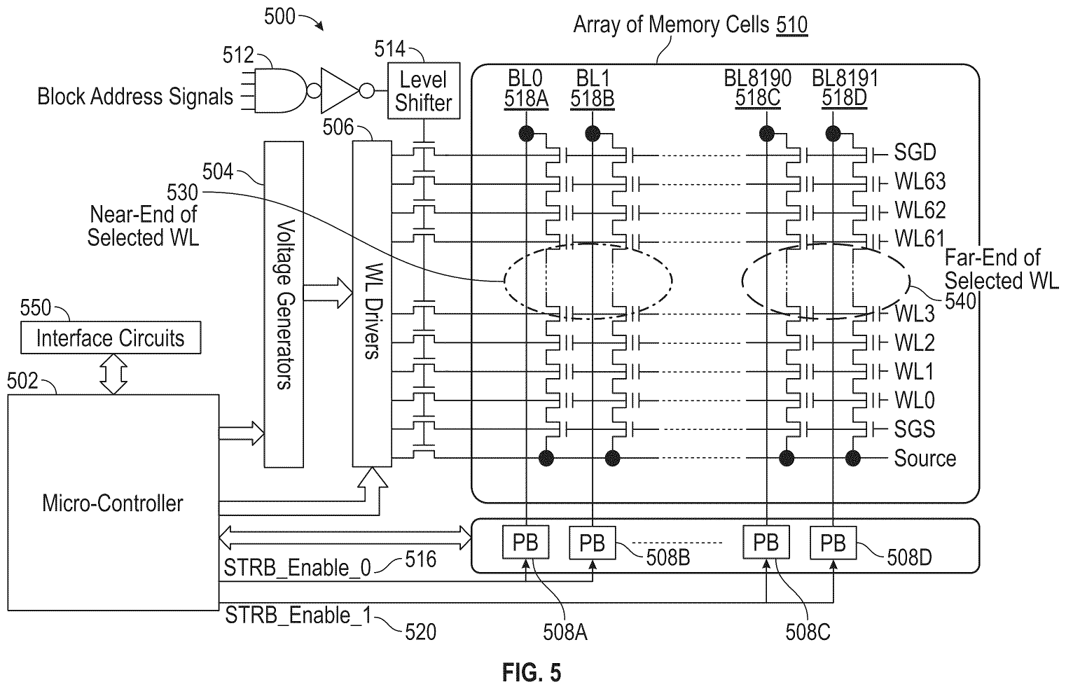

The embodiments herein describe methods and systems for a modified auto calibrated read operation that reduces or minimizes the time required to perform a read level calibration, and therefore reduces or minimizes the latency penalty for performing a read operation using calibrated read levels. For example, a quick operation to detect a threshold voltage distribution for a word line (e.g., a “Get-Vt-Distribution” operation) may be carried out while a word line voltage is ramped up linearly, e.g., at a rate of 0.30V/μsec. A micro-controller (e.g., micro-controller 502 shown in FIG. 5) may calibrate a set of read word line voltage levels from a detected Vₜ distribution, and a read operation may be carried out using a best set of calibrated word line voltage levels. For example, the word line may be ramped up linearly at a slower rate, e.g., 0.15V/μsec, than the ramp rate of the Get-Vt-distribution operation, but the technique allows the read calibration to be carried out within a shorter time.

In an embodiment, a controller is connected to the word line driver and the plurality of page buffers. The controller has a memory storing software instructions (e.g., firmware instructions) which, when executed, cause the controller to perform one or more operations to ramp, via the word line driver, a voltage level of the word line at a first rate of change. The controller is further caused to detect, via the plurality of page buffers, memory cell activation outputs from a subset of the memory cells based on ramping the voltage level of the word line at the first rate of change. The subset of memory cells may be located proximate to a near end of the word line with respect to the word line driver. The memory cell activation outputs may be detected via a subset of the plurality of page buffers, e.g., by enabling one or more strobe signals to detect the memory cell activation outputs. The controller is further caused to calibrate word line read levels for the memory cells based on the detected memory cell activation outputs. The controller is further caused to ramp, via the word line driver, the voltage level of the word line at a second rate of change, and read, via the plurality of page buffers, data stored in the memory cells activated when the voltage level of the word line ramped at the second rate of change reaches the calibrated word line read levels.

In some embodiments, a threshold voltage distribution may be calculated based on the detected memory cell activation outputs, and the read level of the word line may be calibrated based on the threshold voltage distribution. A count fail bit (CFBIT) circuit may be connected to the plurality of page buffers. The CFBIT circuit is configured to count a number of detected memory cell activation outputs, where the threshold voltage distribution may be calculated based on the number of detected memory cell activation outputs. The subset of memory cells may comprise one of the following: about 50% of the memory cells, about 25% of the memory cells, or about 10% of the memory cells.

In some embodiments, the first rate of change of the voltage level may be different from the second rate of change of the voltage level. The first rate of change of the voltage level may be greater than the second rate of change of the voltage level, or about twice the second rate of change of the voltage level.

In some embodiments, the voltage level at the first rate of change may be changed from a lower voltage level to a higher voltage level. The first rate of change of the voltage level may be about +0.30V/μs.

In some embodiments, the voltage level at the first rate of change may be changed from a higher voltage level to a lower voltage level. The first rate of change of the voltage level may be about −0.30V/μs.

In some embodiments, the second rate of change of the voltage level may be about +0.15V/μs.

In some embodiments, the memory cells may comprise quad-level memory cells, and fifteen strobe signals may be enabled to detect the memory cell activation outputs.

In some embodiments, the word line driver may comprise a bit counter or voltage generator to generate digital progressive values, and a digital to analog converter (DAC) to convert the digital progressive values into an analog ramp signal operable to linearly ramp the voltage level, e.g., by applying N-step voltage pulses at each ramp step of the word line.

A program operation of a NAND memory device comprises a programming phase and a verification phase. The programming phase includes repeating the application of an incremental-step program pulse to a word line connected to memory cells, while the verification (program verify) phase includes verifying the program states of the memory cells. In quad-level memory cells, the time required to verify each of the program levels becomes dominant with respect to overall programming time.

In an embodiment, a program verify operation is initiated for each stage of a word line based on a CFBIT result. This technique allows for a word line voltage to be reset to a recovery state earlier when the CFBIT result indicates that all memory cells in each stage of the word line have turned on. For example, a program operation comprising an application of a programming pulse and a program verify operation is initiated for each stage of a word line. An indication is detected, via the plurality of page buffers, that a threshold number of the memory cells corresponding to a stage of the word line are activated during the program verify operation. The indication may be based on activation outputs detected from the memory cells. The program verify operation for a stage of the word line may be determined to be completed based on the indication that the threshold number of the memory cells corresponding to the stage of the word line are activated, and a word line voltage level recovery operation may be initiated based on the indication. The program verify operation is reset based on the indication, where the reset program verify operation is not applied to at least one stage of the word line based on previously applied programming pulses or program verify operations. Not applying the reset program verify operation to at least one stage of the word line may comprise not applying the reset program verify operation to a stage of the word line for which a program verify operation has been previously applied.

In some embodiments, the stage of the word line for which the program verify operation has been previously applied may be determined based on a threshold number of bits detected in the stage of the word line during a program verify operation.

In some embodiments, not applying the reset program verify operation to at least one stage of the word line may comprise not applying the reset program verify operation to a stage of the word line for which a programming pulse has not yet been applied.

In some embodiments, a count fail bit (CFBIT) circuit may be connected to the plurality of page buffers, the CFBIT circuit to count a number of bits corresponding to a number of activation outputs from the memory cells; and provide the indication when the number of bits detected reaches a threshold number of bits. A tolerance value may be applied to confirm the threshold number of bits, or the threshold number of bits may comprise a maximum number of bits for a stage of the word line.

In some embodiments, a number of stages of the word line may be based on a number a memory cell levels, where the memory cells comprise tri-level memory cells or quad-level memory cells.

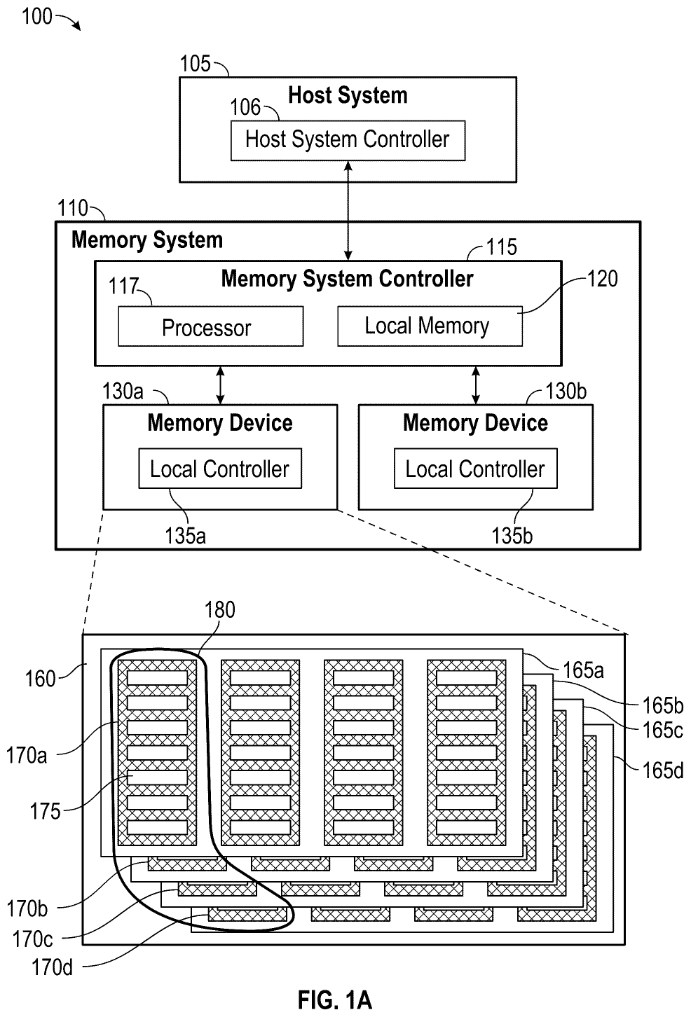

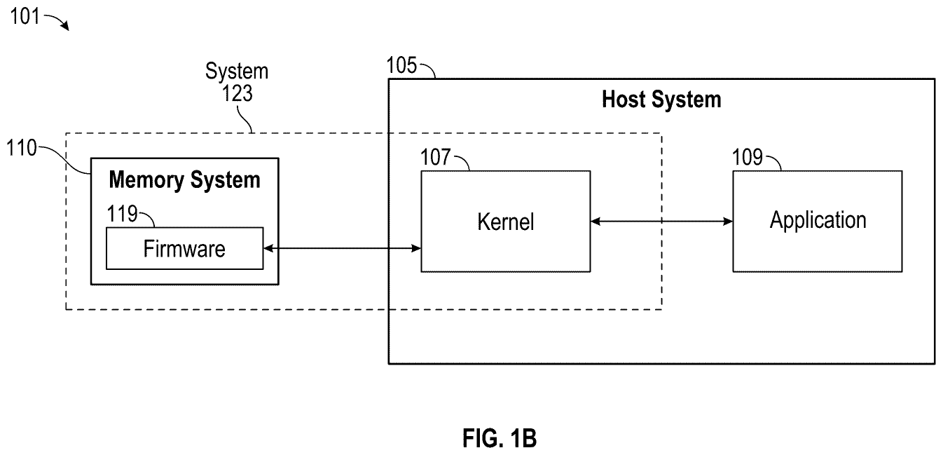

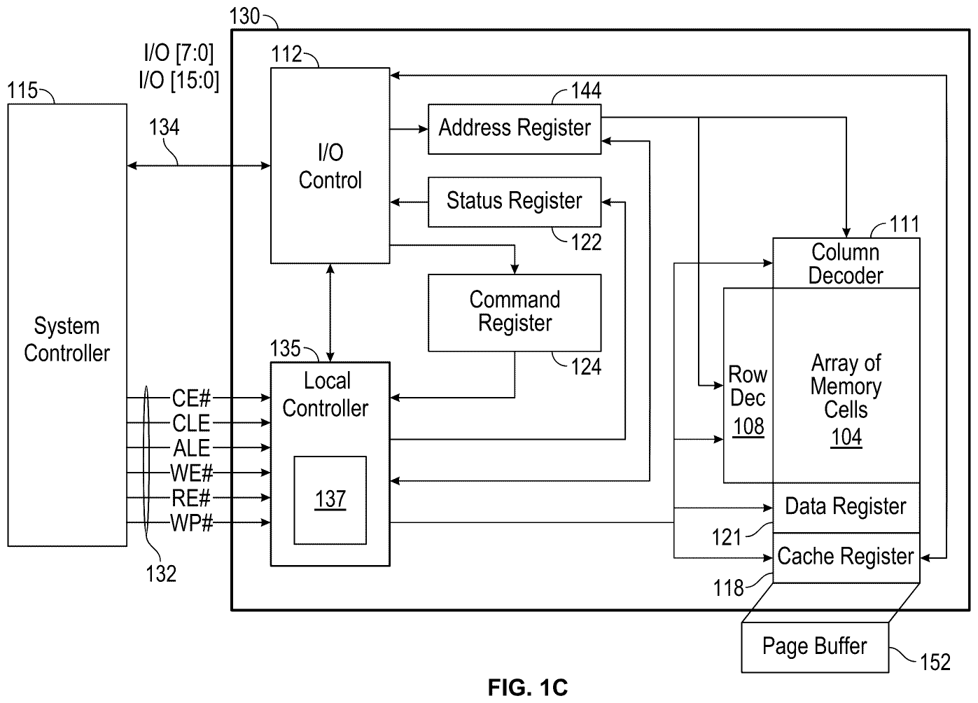

FIG. 1A illustrates an example of a system 100 that supports techniques for implementing an auto calibrated read operation and an efficient program verification operation in accordance with examples as disclosed herein. System 100 includes a host system 105 coupled with a memory system 110. System 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

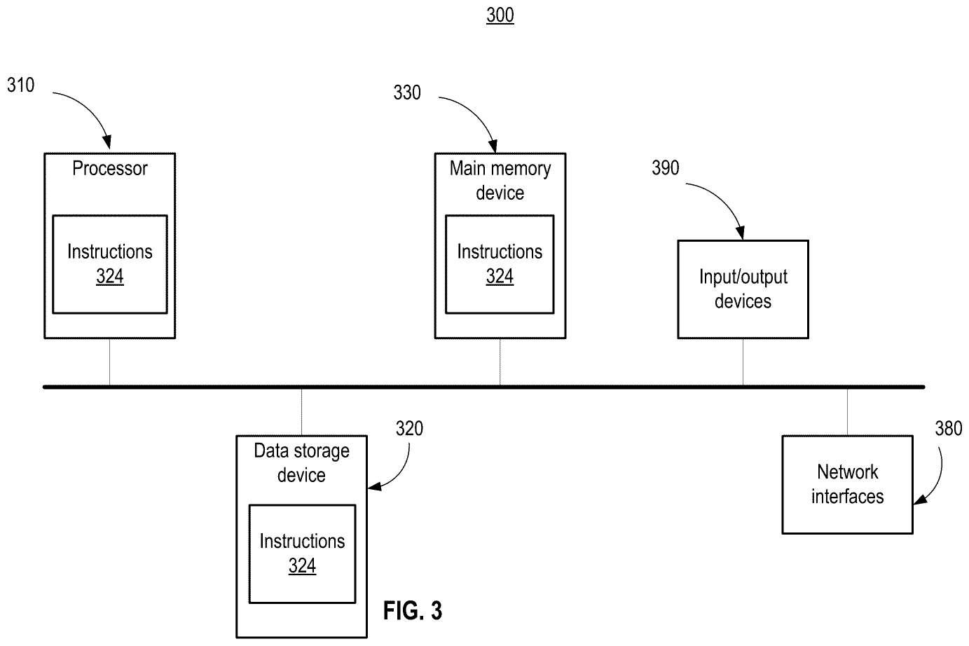

System 100 may include a host system 105, which may be coupled with memory system 110. In some examples, this coupling may include an interface with a host system controller 106, which may be an example of a controller or control component configured to cause host system 105 to perform various operations in accordance with examples as described herein. Host system 105 may include one or more devices and, in some cases, may include a processor chipset and a software stack executed by the processor chipset. Host system 105 may be implemented by, for example, an apparatus 300 shown in FIG. 3. For example, host system 105 may include an application configured for communicating with memory system 110 or a device therein. The processor chipset may include one or more cores, one or more caches (e.g., memory local to or included in host system 105), a memory controller (e.g., NVDIMM controller), and a storage protocol controller (e.g., peripheral component interconnect express (PCIe) controller, serial advanced technology attachment (SATA) controller). Host system 105 may use memory system 110, for example, to write data to memory system 110 and read data from memory system 110. Although one memory system 110 is shown in FIG. 1A, the host system 105 may be coupled with any quantity of memory systems 110.

Host system 105 may be coupled with memory system 110 via at least one physical host interface. Host system 105 and memory system 110 may, in some cases, be configured to communicate via a physical host interface using an associated protocol (e.g., to exchange or otherwise communicate control, address, data, and other signals between memory system 110 and host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a Graphical Double Data Rate (GDDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of host system 105 and a system controller 115 of memory system 110. In some examples, host system 105 may be coupled with memory system 110 (e.g., host system controller 106 may be coupled with system controller 115) via a respective physical host interface for each memory device 130 included in the memory system 110, or via a respective physical host interface for each type of memory device 130 included in memory system 110.

Memory system 110 may include a system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1A, memory system 110 may include any quantity of memory devices 130. Further, if the memory system 110 includes more than one memory device 130, different memory devices 130 within the memory system 110 may include the same or different types of memory cells.

System controller 115 may be coupled with and communicate with host system 105 (e.g., via the physical host interface) and may be an example of a controller or control component configured to cause memory system 110 to perform various operations in accordance with examples as described herein. System controller 115 may also be coupled with and communicate with memory devices 130 to perform operations such as reading data, writing data, erasing data, or refreshing data at a memory device 130—among other such operations—which may generically be referred to as access operations. In some cases, system controller 115 may receive commands from the host system 105 and communicate with one or more memory devices 130 to execute such commands (e.g., at memory arrays within the one or more memory devices 130). For example, system controller 115 may receive commands or operations from host system 105 and may convert the commands or operations into instructions or appropriate commands to achieve the desired access of memory devices 130. In some cases, system controller 115 may exchange data with host system 105 and with one or more memory devices 130 (e.g., in response to or otherwise in association with commands from host system 105). For example, system controller 115 may convert responses (e.g., data packets or other signals) associated with the memory devices 130 into corresponding signals for the host system 105.

System controller 115 may be configured for other operations associated with the memory devices 130. For example, the system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from host system 105 and physical addresses (e.g., physical block addresses) associated with memory cells within memory devices 130.

The system controller 115 may include hardware such as one or more integrated circuits or discrete components, a buffer memory, or a combination thereof. The hardware may include circuitry with dedicated (e.g., hard-coded) logic to perform the operations ascribed herein to system controller 115. System controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

System controller 115 may also include a local memory 120. In some cases, local memory 120 may include read-only memory (ROM) or other memory that may store operating code (e.g., executable instructions) executable by system controller 115 to perform functions ascribed herein to system controller 115. In some cases, local memory 120 may additionally, or alternatively, include static random-access memory (SRAM) or other memory that may be used by system controller 115 for internal storage or calculations, for example, related to the functions ascribed herein to system controller 115.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on a same semiconductor die or within a same package) a local controller 135, which may execute operations on one or more memory cells of the respective memory device 130. A local controller 135 may operate in conjunction with a system controller 115 or may perform one or more functions ascribed herein to the system controller 115. For example, as illustrated in FIG. 1A, a memory device 130-a may include a local controller 135-a and a memory device 130-b may include a local controller 135-b. In the examples illustrated in this disclosure (e.g., the example shown in FIG. 1C), local controller 135 is disposed on the same semiconductor die as the memory array (e.g., array 104); and a separate system controller 115 is disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or another circuitry of device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of memory blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of memory blocks 170 and, in some cases, concurrent operations may be performed on different planes 165. For example, concurrent operations may be performed on memory cells within different blocks 170 so long as the different blocks 170 are in different planes 165. In some cases, an individual memory block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line). Example memory cells structures are shown in more detail below using illustrative schematics.

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a memory block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, L2P (logical-to-physical) mapping tables may be maintained, and data may be marked as valid or invalid at the page level of granularity, and a page 175 may contain valid data, invalid data, or no data. Invalid data may be data that is outdated, which may be due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has never been written to or that has been erased.

In some cases, a memory system 110 may utilize a system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

System 100 may include any quantity of non-transitory computer readable media that support techniques for logical-to-physical table compression. For example, host system 105 (e.g., a host system controller 106), memory system 110 (e.g., a system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a system controller 115), or by a memory device 130 (e.g., by a local controller 135), may cause the host system 105, the memory system 110, or the memory device 130 to perform associated functions as described herein.

In some cases, a memory system 110 may compress an L2P mapping to expand the quantity of physical addresses mapped by the L2P mapping. For example, if a set of consecutive entries of an uncompressed L2P mapping includes consecutive physical addresses, memory system 110 may compress the consecutive entries into a single entry which includes a starting physical address of the consecutive physical addresses. Additionally, memory system 110 may include an indication of a starting logical address corresponding to the starting physical address in the compressed entry. To identify a physical address within the compressed entry, memory system 110 may determine an offset between a logical address corresponding to the physical address (e.g., a logical address included in a read command for data stored at the physical address) and the starting physical address using the indication and may apply the offset to the starting physical address to determine the physical address. Compressing the L2P mapping may allow the L2P mapping to cover an expanded range of physical address space without increasing the size of the L2P mapping.

FIG. 1B illustrates an example of a system diagram 101 that illustrates communication between host system 105 and memory system 110 via using a kernel and firmware, in accordance with examples as disclosed herein. System diagram 101 may include a memory system 110, a kernel 107, and an application 109. The memory system 110 may include a firmware 119. Firmware 119 may be implemented by a controller and/or other circuitry of the memory system (e.g., system controller 115 and/or local controllers 135 shown in FIG. 1A). In some examples, a system 123 as described herein may include memory system 110 and kernel 107. Additionally, a host system 105 may include kernel 107 and the application 109.

As described above, memory system 110 may include multiple memory devices, including non-volatile memory devices and volatile memory devices (e.g., local memory 120), configured to store and retrieve data. Firmware 119 may refer to software stored within a memory array within memory system 110 (e.g., a non-volatile memory device within the memory system 110) and/or a local memory 120 as shown in FIG. 1A. Firmware 119 may provide low-level control functions for the memory system 110. For example, firmware 119 may function as an interface between the memory system 110 and other components of the system 123, and host system 105 may issue access operations to memory system 110 by interfacing with firmware 119. In some examples, firmware 119 may be or be included within or implemented by a system controller 115, as described herein with reference to FIG. 1A. In some examples, memory system 110 may store a logical-to-physical mapping that maps logical addresses to physical addresses within a non-volatile memory device (e.g., in a logical-to-physical table). To perform a memory access operation, memory system 110 may move a portion of the logical-to-physical mapping corresponding to one or more logical addresses (e.g., indicated by kernel 107) from the non-volatile memory device to a volatile memory device.

Kernel 107 may function as an interface between host system 105 and components associated with host system 105, such as an operating system of host system 105. Additionally, kernel 107 may perform resource allocation and file management, among other operations, for host system 105. For example, an application 109 running within host system 105 may access information stored within memory system 110 by issuing commands to kernel 107, which may indicate files to be accessed. Kernel 107 may store mapping information associated with the files. For example, a file may be associated with a file name, and may correspond to a range of logical block addresses. Kernel 107 may store mapping information (e.g., a mapping table) that may track logical block addresses corresponding to files of host system 105. In some examples, application 109 may issue an access command to kernel 107 indicating a file name, and offset, and a length associated with a file to be accessed, and kernel 107 may retrieve a one or more logical block addresses corresponding to the file to be accessed. Kernel 107 may then communicate with firmware 119 to indicate the one or more logical block addresses to memory system 110, and memory system 110 may perform an access operation based on the one or more logical block addresses. Memory system 110 may communicate the accessed information to kernel 107 (e.g., via the firmware 119).

In some examples, kernel 107 may communicate with to firmware 119 using information units (e.g., UFS protocol information units (UPIUs)). For example, kernel 107 may issue or receive commands, responses, data, or other information via information units exchanged with the firmware 119. An information unit may refer to a data packet that may contain a header segment and one or more transaction specific fields. In some examples, an information unit may additionally include one or more extended header segments, one or more data segments, or a combination thereof. The header segments of an information unit may indicate information associated with a destination for the information unit, a source of the information unit, a function request, whether additional data or parameters are to be transmitted, whether the additional data or parameters are included within the information unit or to be sent in a following information unit, or any combination thereof. The transaction specific fields may be used for additional fields depending on the operation associated with the information unit. The data segments may be used to include data to be transferred from a device to another.

In some examples, a command information unit (e.g., a command UPIU) may be an example of an information unit associated with the transmission of a command (e.g., an SCSI command) and may indicate a device to perform some operation indicated by the command information unit. For example, the command information unit may include a block descriptor (e.g., a command descriptor block) which may indicate information related to the operation indicated by the command information unit. In some examples, kernel 107 may transfer a command information unit to memory system 110 to indicate memory system 110 of an operation to be performed by memory system 110.

In some examples, to perform an access operation, memory system 110 may load a L2P mapping associated with information to be accessed. For example, memory system 110 may transfer a portion of a logical-to-physical mapping associated with the information to be accessed from a non-volatile memory device of memory system 110 (e.g., NAND memory) to a volatile memory device (e.g., an SRAM) of the memory system 110. In another example, host system 105 may notify memory system 110 of a logical block address range corresponding to an upcoming access operation (e.g., prior to issuing an access command). Memory system 110 may use the logical block address range to load (e.g., pre-load, pre-fetch) an associated portion of a L2P mapping (e.g., from a non-volatile memory device to a volatile memory device) prior to receiving an access command that indicates memory system 110 to perform the access operation. Accordingly, after host system 105 issues the access command, memory system 110 may issue a response to host system 105 faster as memory system 110 has already loaded relevant portions of the L2P mapping associated with the access operation.

The above description of the system diagram 101 are illustrative examples of communication between host system 105 and memory system 110 by using a kernel 107, application 109, and firmware 119. It is understood that additional ways of communication, including function calls, commands, responses, messages, etc. can be implemented using host system 105 and memory system 110, and/or additional systems or components.

FIG. 1C is a simplified block diagram of a memory device 130 in communication with a system controller 115 of a memory system (e.g., the memory system 110 of FIGS. 1A and 1B), according to an embodiment. A memory system may be or include any device or collection of devices, where the device or collection of devices includes at least one memory array. For example, a memory system may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices. A memory system may communicate with a host system, which may include a host system controller. The host system may be implemented using one or more processors and a memory system for writing data to the memory system, reading data from the memory system, erasing data, or refreshing data.

A memory system may include one or more memory devices, such as device 130. A memory device 130 may include one or more memory arrays of any type of memory cells (e.g., non-volatile memory cells, volatile memory cells, or any combination thereof). For example, memory device 130 may include NAND (e.g., NAND flash) memory, ROM, phase change memory (PCM), NOR (e.g., NOR flash) memory, etc. In some cases, memory device 130 is a NAND memory device 130, may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

As shown in FIG. 1C and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1C) of at least a portion of the array of memory cells 104 are capable of being programmed to one of at least two target data states for storing any number of bits of information.

With continued reference to FIG. 1C, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 114 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

A memory controller (e.g., the local controller 135 internal to memory device 130) controls access to the array of memory cells 104 in response to the commands and generates status information for the external system controller 115, i.e., the local controller 135 is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses.

In some embodiments, local controller 135 communicates with the external system controller 115, which may be a host controller (e.g., an UFS or eMMC controller, or a CPU communicating with local controller 135) located in a host system or a memory system controller located in a memory system. In some embodiments, local controller 135 is disposed on the same semiconductor die as the memory array (e.g., array 104), and a separate system controller 115 is disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

Local controller 135 is also in communication with a cache register 118 and a data register 121. In some embodiments, one or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the system controller 115; then new data can be passed from the data register 121 to cache register 118. In some embodiments, cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to system controller 115.

As shown in FIG. 1C, memory device 130 receives various control signals via local controller 135 from system controller 115 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 132 depending upon the nature of memory device 130. In one embodiment, memory device 130 receives command signals (which represent commands), address signals (which represent addresses), and data signals (which represent data) from the system controller 115 over a multiplexed input/output (I/O) bus 134 and outputs data to the system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 114. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1C has been simplified. It should be recognized that the functionality of the various block components described with reference to FIG. 1C may not necessarily be segregated to distinct components or component portions of an integrated circuit device. For example, a single component or component portion of an integrated circuit device could be adapted to perform the functionality of more than one block component of FIG. 1C. Alternatively, one or more components or component portions of an integrated circuit device could be combined to perform the functionality of a single block component of FIG. 1C. Additionally, while specific I/O pins are described in accordance with popular conventions for receipt and output of the various signals, it is noted that other combinations or numbers of I/O pins (or other I/O node structures) can be used in the various embodiments.

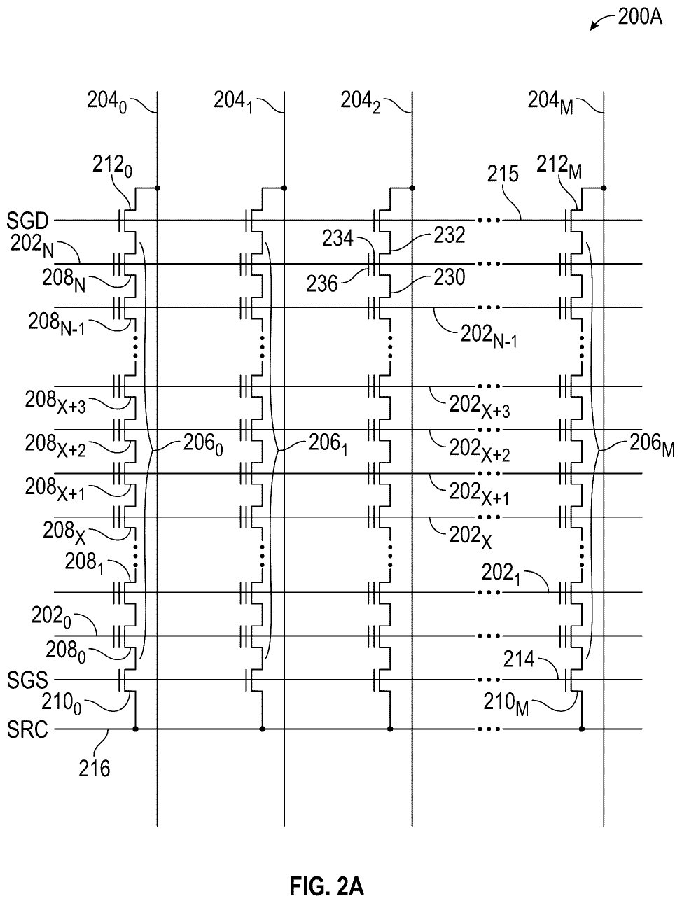

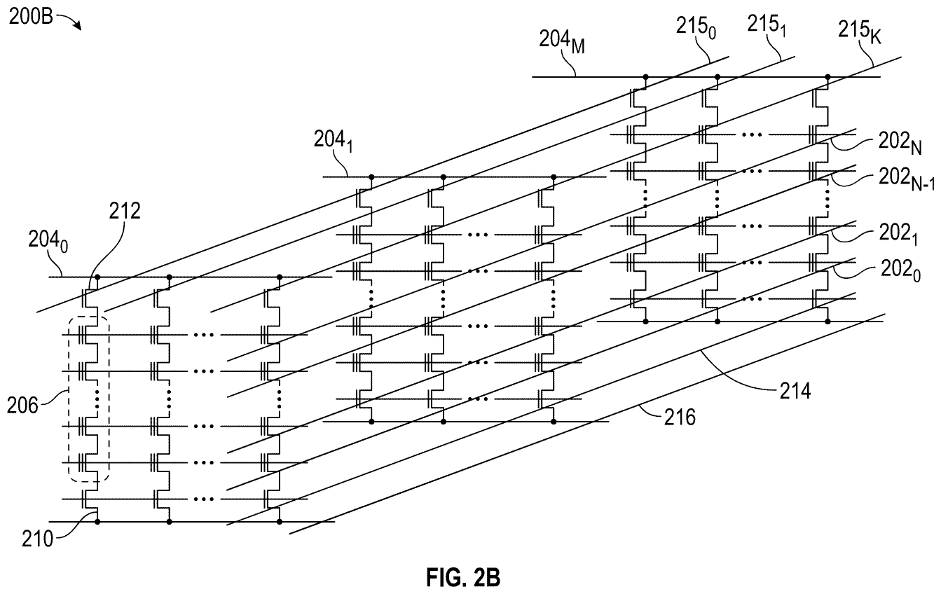

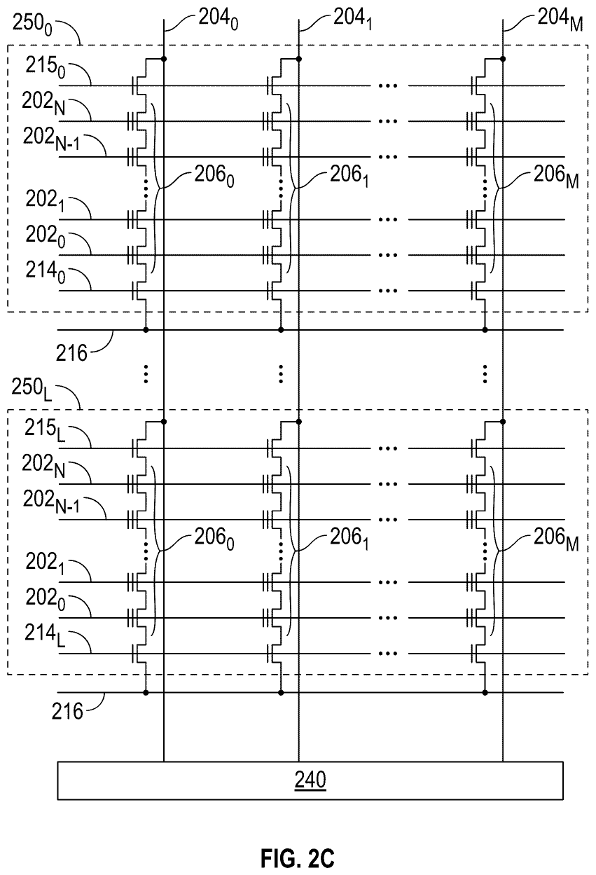

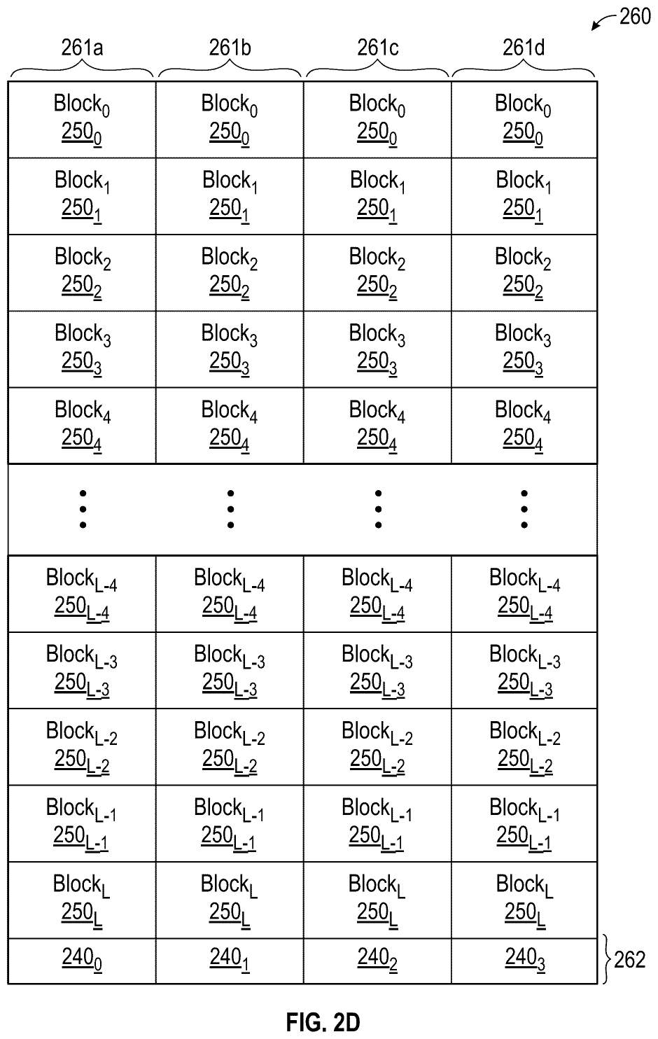

FIG. 2A-2B are example schematics of portions of an array of memory cells 200A, such as a NAND memory array. Array of memory cells 200A may be an example of memory array 104 of a memory device 130 as described with reference to FIG. 1C according to an embodiment. Memory array 200A includes access lines, such as word lines 202₀ to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select transistor 210 (e.g., a field-effect transistor), such as one of the select gates 210₀ to 210_{M} (e.g., that can be source select transistors, commonly referred to as select gate source), and a select transistor 212 (e.g., a field-effect transistor), such as one of the select transistors 212₀ to 212 (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select transistors 210 and 212 can utilize a structure similar to (e.g., the same as) the memory cells 208. The select transistors 210 and 212 can represent a number of select gates connected in series, with each select transistor in series configured to receive a same or independent control signal.

A source of each select transistor 210 can be connected to common source 216. The drain of each select transistor 210 can be connected to a memory cell 208₀ of the corresponding NAND string 206. For example, the drain of select gate 210₀ can be connected to memory cell 208₀ of the corresponding NAND string 206₀. Therefore, each select transistor 210 can be configured to selectively connect a corresponding NAND string 206 to the common source 216. A control gate of each select transistor 210 can be connected to select line 214.

The drain of each select transistor 212 can be connected to bit line 204 for the corresponding NAND string 206. For example, the drain of select gate 212₀ can be connected to the bit line 204₀ for the corresponding NAND string 206₀. The source of each select transistor 212 can be connected to a memory cell 208_{N} of the corresponding NAND string 206. For example, the source of select gate 212₀ can be connected to memory cell 208_{N} of the corresponding NAND string 206₀. Therefore, each select transistor 212 can be configured to selectively connect a corresponding NAND string 206 to the corresponding bit line 204. A control gate of each select transistor 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device 130, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

In some examples, memory cells can be grouped into memory blocks. FIG. 2C depicts groupings of NAND strings 206 into blocks of memory cells 250, e.g., blocks of memory cells 250₀-250₁. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀ can be a same source as the source 216 for the block of memory cells 250_{L}. For example, each block of memory cells 250₀-250_{L}, can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bit lines 204.

FIG. 2D is a block schematic of a portion of an example array of memory cells 260. Array of memory cells 260 can be used as array 104 in a memory device 130. The array of memory cells 260 is depicted as having four memory planes 261 (e.g., memory planes 261a-261d). Each of the memory planes 261 may refer to a group of memory blocks of memory cells 250. Each memory plane 261 can be in communication with a respective buffer portion 240, which can collectively form a page buffer 262. Page buffer 262 may be used to implement page buffer 152 shown in FIG. 1C. While four memory planes 261 are depicted, other numbers of memory planes 261 can be commonly in communication with a page buffer 262. Each memory plane 261 is depicted to include L+1 blocks of memory cells 250 (e.g., blocks of memory cells 250₀-250_{L}).

In some cases, concurrent operations may be performed on different planes. For example, concurrent operations may be performed on memory cells within different blocks 250 so long as the different blocks 250 are in different planes 261. In some cases, an individual memory block 250 may be referred to as a physical block, and a virtual block may refer to a group of blocks 250 within which concurrent operations may occur. For example, concurrent operations may be performed on four blocks of 250₀ that are within planes 261a, 261b, 261c, and 261d, respectively, and the four blocks of 250₀ may be collectively referred to as a virtual block. In some cases, a virtual block may include blocks from different memory devices. In some cases, the physical blocks within a virtual block may have the same block address within their respective planes. In some cases, performing concurrent operations in different planes 261 may be subject to one or more restrictions, such as concurrent operations being performed on memory cells within different pages that have the same page address within their respective planes 261 (e.g., related to command decoding, page address decoding circuitry, or other circuitry being shared across planes 261).

In some cases, a block 250 may include memory cells organized into rows (pages) and columns (e.g., strings, not shown). For example, memory cells in a same page may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page may be the smallest unit of memory (e.g., set of memory cells) that may be independently programmed or read (e.g., programed or read concurrently as part of a single program or read operation), and a memory block 170 may be the smallest unit of memory (e.g., set of memory cells) that may be independently erased (e.g., erased concurrently as part of a single crase operation). Further, in some cases, NAND memory cells may be erased before they can be re-written with new data. Thus, for example, a used page may, in some cases, not be updated until the entire block that includes the page has been erased.

With continued reference to FIGS. 1C and 2A-2C, during a true erase operation (during which memory cells are actually being erased), the local controller 135 (e.g., using an crase operation manager 137) can cause a common source voltage line, e.g., the SRC 216 (FIG. 2A), to be ramped to an crase voltage (VERA) with an erase pulse while the select gates 210₀ to 210_{M} (SGS transistors) are turned on. Ramping to this high bias erase voltage, and the subsequent recovery from this voltage ramping, may take a significant amount of time. Concurrently, the erase operation manager 137 can cause the select gates 212₀ to 212m (FIG. 2A) to be turned off to enable the drains of the select gates 2120 to 212m to float, which causes the bit lines 204₀ to 204_{M} to also float. Further, the erase operation manager 137 can couple the word lines 202 (FIG. 2A) to ground, e.g., zero volts, or retain the word lines 202 at a low voltage. This set of voltage levels at the memory array 200A can create an erase potential that causes the memory cells 208₀ to 208x to be erased, e.g., forces electrons to exit through a body of each memory cell and out the floating bit lines 204₀ to 204_{M}. In other embodiments, the reverse can be done so the select gates 210₀ to 210_{M} are turned off, causing the SRC line 216 to float while the voltage of the bit lines are ramped to Vera while the select gates 212₀ to 212_{M} are turned on. As mentioned earlier, in 3D NAND, one of the channel region, pillar, or bit line can also be ramped up in voltage to cause erasure of attached memory cells. Thus, for simplicity herein, reference to “memory line” should be understood to make reference to any of the SRC line or bit lines in 2D NAND or to any of channel, pillar, or bit lines in 3D NAND. In some embodiments, one or more sub-blocks, to include a physical block, of memory cells are erased during the same true erase operation. A block of memory cells can be generally understood to include four or more sub-blocks, wherein each sub-block includes a separate string of memory cells.

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of the FIGS. 1A-3 & 5-16, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system that includes, is coupled to, or utilizes a memory system (e.g., memory system shown in FIG. 1C). Apparatus 300 can be used to perform operations of a controller (e.g., to execute an operating system to perform operations corresponding to system controller 115 and/or local controller 135 of FIG. 1C).

In some embodiments, apparatus 300 comprises a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., system controller 115 and/or local controller 135 of FIG. 1C). The computer program instructions 324 may be stored in data storage device 320, or other computer-readable medium, and loaded into main memory device 330 when execution of the computer program instructions is desired. For example, processor 310 may be used to implement one or more components and systems described herein, such as system controller 115 and/or local controller 135 (shown in FIG. 1C). Thus, the method steps of at least some of FIGS. 1A-3 & 5-16 can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the method steps discussed herein in connection with at least some of FIGS. 1A-3 & 5-16. Accordingly, by executing the computer program instructions, processor 310 executes an algorithm defined by the method steps of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may comprise one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each comprise a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 320 may be implemented using the memory system (e.g., system shown in FIG. 1C) described herein. In some examples, data storage device 320 and main memory device 330 may include one or more memory devices 130 (FIG. 1C).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

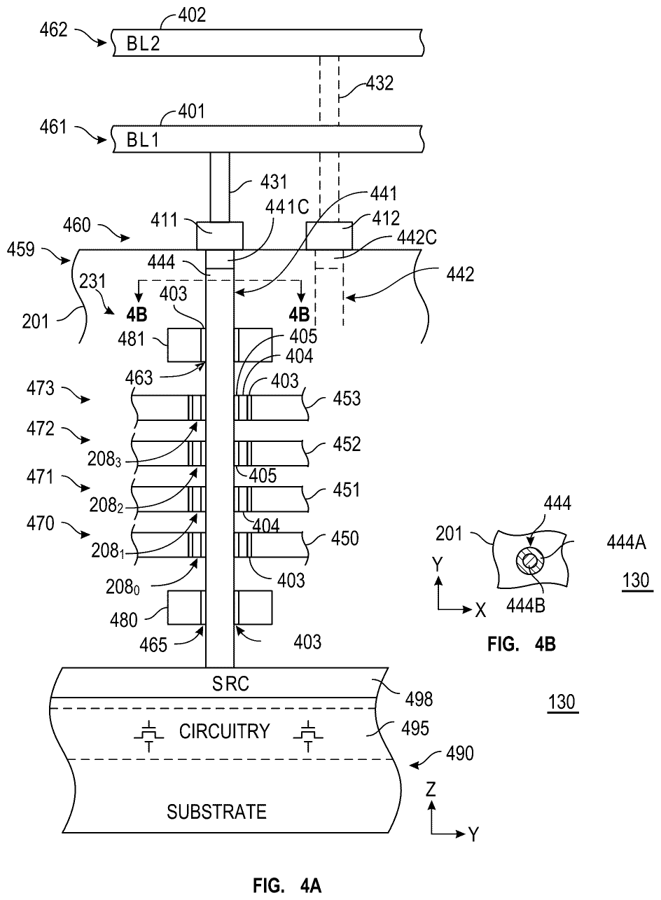

FIGS. 4A-4B show a side view (e.g., a cross section with respect to the X-Z directions) of a portion of the three-dimensional structure of memory device 130 including a structure of memory cell string 231 (e.g., a NAND string) having a pillar 441, according to some embodiments described herein. FIG. 4A shows the structure of one memory cell string (e.g., memory cell string 231) of memory device 130. However, other memory cell strings (e.g., NAND strings 206₀-206_{M} in FIG. 2A and NAND strings 206 in FIG. 2B) can have a similar or the same structure as memory cell string 231 shown in FIG. 4A.

Starting from the top of FIG. 4A, memory device 130 have data lines 401 and 402 (e.g., corresponding to bit lines 204 in FIGS. 2A, 2B, and 2C) coupled to conductive structures 431 and 432, respectively, and coupled to conductive contacts 411 and 412, respectively. Data lines 401 and 402 are therefore electrically connected to pillars 441 and 442, respectively, via the conductive contacts 411 and 412, respectively. It is understood that memory device 130 can include many other similar data lines, conductive structures, and conductive contacts, which are not shown for simplicity.

FIGS. 4A-4B show directions X, Y, and Z that can be relative to the physical directions (e.g., dimensions) of the structure of memory device 130. For example, the Z-direction can be a direction perpendicular to (e.g., vertical direction relative to) a substrate (e.g., a semiconductor substrate) of memory device 130. The Z-direction is perpendicular to the X-direction and Y-direction (e.g., the Z-direction is perpendicular to an X-Y plane of memory device 130).

As shown in FIG. 4A, data lines 401 and 402 can carry signals (e.g., bit line signals) BL1 and BL2, respectively. In the physical structure of memory device 130, data lines 401 and 402 can be structured as conductive lines and have respective lengths extending in the Y-direction. The data lines (e.g., data lines 401 and 402) of memory device 130 can be formed on different levels (e.g., layers) in the physical structure of memory device 130. For example, data lines 401 can be formed on one level (e.g., a lower level 461) of memory device 130, and data lines 402 can be formed on another level (e.g., an upper level 462) of memory device 130. Although not shown in FIG. 4A, multiple data lines can be located side-by-side in any particular level. For example, level 461 may have multiple data lines and level 462 may also have multiple data lines. Data lines in the same level can be separated from each other by a distance (e.g., a gap) in the X-direction. The gaps between data lines in the same level may be the same or different. As shown in FIG. 4A, each of data lines 401 and 402 can have a thickness in the Z-direction and a width in the X-direction. Each of the thickness (in the Z-direction) and the width (in the X-direction) is less than the length (in the Y-direction). The thickness can be less than, equal to, or greater than the width.

In FIG. 4A, each of conductive structures 431 and 432 can have a length extending in the Z-direction. In some examples, the length of conductive structure 431 can be less than the length of conductive structure 432, because level 461 is a lower level that is located closer to memory array 201. Each of conductive structures 431-432 can include (e.g., can be formed from) a conductive material that extends in the Z-direction. Examples of the conductive material include metal, alloy, conductively doped polysilicon, or other conductive materials. Although not shown in FIG. 4A, memory device 130 can include a dielectric material (e.g., silicon dioxide) formed between levels 462 and 461. The dielectric material can be formed before conductive structures 431 and 432. Then, openings (e.g., holes (e.g., vertical vias)) can be formed in the dielectric material. The material of each of conductive structures 431-432 can be formed (e.g., deposited) inside a respective opening of the openings.

As shown in FIG. 4A, each of conductive structures 431 and 432 can be coupled to (e.g., in electrical contact with) a respective conductive contact among conductive contacts 411 and 412 and coupled to (e.g., in electrical contact with) a respective data line among data lines 401 and 402. For example, conductive structure 431 can include an end (e.g., bottom end) coupled to (e.g., directly contacting) conductive contact 411, and another end (e.g., top end) coupled to (e.g., directly contacting) data line 401. In another example, conductive structure 432 can include an end (e.g., bottom end) coupled to (e.g., directly contacting) conductive contact 412, and another end (e.g., top end) coupled to (e.g., directly contacting) data line 402.

As shown in FIG. 4A, memory cell string 231 can include pillars (e.g., vertical pillars) 441 and 442. Pillars 441 and 442 can include pillar contacts 441C and 442C, respectively, located on the same level (e.g., level 459) of memory device 130. Pillars 441 and 442 can be located under (e.g., directly under) respective conductive contacts 411 and 412, which are under (e.g., directly under) respective conductive structures 431 and 432. Conductive structures 431 and 432 can be coupled to (e.g., in electrical contact with) pillars 441 and 442, respectively, through conductive contacts 411 and 412, respectively. Thus, as shown in FIG. 4A, data lines 401 and 402 can be coupled to (e.g., electrically coupled to) pillars 441 and 442, respectively, through respective conductive structures 431 and 432 and respective conductive contacts 411 and 412.

As described above, data lines 401 and 402 are located in levels 461 and 462, respectively. Levels 461 and 462 are in portion of memory device 130 that is located above memory array 201 in the Z-direction. Memory array 201 is located above a substrate 490 of memory device 130 in the Z-direction. As described above, a memory array such as memory array 201 comprises multiple memory cell strings (one of which is shown as memory cell string 231).

As shown in FIG. 4A, pillar (e.g., a vertical pillar) 441 can be a part of memory cell string 231 and can have a length extending in the Z-direction (e.g., extend vertically with respect to substrate 490). Pillar 441 can extend through memory cells 208₀, 208₁, 208₂, and 208₃ of memory cell string 231. Pillar 441 can include (e.g., can be formed from) a conductive material (e.g., conductively doped polysilicon). Each of memory cells 208₀, 208₁, 208₂, and 208₃ can include a structure of transistor (e.g., a memory cell transistor). Part of pillar 441 can form the channel region (e.g., to conduct current) of the transistor of each memory cells 208₀, 208₁, 208₂, and 208₃. It is understood that while FIG. 4A only shows four memory cells 208₀-208₃, memory cell string 231 can include any number of memory cells that share a same pillar (e.g., pillar 441).

As described above, pillar contact 441C can be formed from conductively doped polysilicon, metal, or other conductive materials. Pillar 441 can include a portion 444. Pillar contact 441C and portion 444 of pillar 441 can include the same conductive material or different conductive materials. Conductive structure 431, conductive contact 411, and pillar 441 can be part of a circuit path (e.g., a conductive channel of memory cell string 231) between data line 401 and a conductive region 498 (associated with an SRC line). Conductive region 498 can be a part of a common source line (e.g., common source line or source plate 216 in FIG. 2A). Conductive structure 431 and pillar 441 can have the same material or different materials. In FIG. 4A, during a memory operation (e.g., read or write operation) of memory device 130, a circuit path (e.g., a current path) can be formed between data line 401 and conductive region 498 through conductive structure 431, conductive contact 411, and pillar 441 (which includes pillar contact 441C and portion 444 of pillar 441).

Substrate 490 of memory device 130 can include a semiconductor substrate (e.g., silicon-based substrate). For example, substrate 490 can include a p-type silicon substrate or an n-type silicon substrate. As shown in FIG. 4A, memory cells 208₀, 208₁, 208₂, and 208₃ of memory cell string 231 can be located along (e.g., adjacent) respective portions of pillar 441 in different levels (in the Z-direction) of memory device 130. For example, memory cells 208₀, 208₁, 208₂, and 208₃ can be located one over another (e.g., formed vertically) in levels 470, 471, 472, and 473, respectively, of memory device 130. Memory cells of other memory cell strings of memory device 130 can also be located on respective levels 470, 471, 472, and 473.

By stacking the memory cells in different levels, the memory device forms a 3D structure that has a higher capacity than a 2D device. In a typical 3D memory device (e.g., device 130 shown in FIG. 4A), for example, multiple levels (e.g., levels 470, 471, 472, and 473) are stacked together with one or more memory pillars (e.g., pillars 441 and 442) disposed vertically in the middle. The memory pillars may act as the channel region of the memory device. The multiple levels (e.g., layers or tiers) of the memory device may form groups or decks. A deck of a 3D memory device may be processed together (e.g., patterned and/or etched together) when forming the memory pillar associated thereof. A level of the memory device may have one or more access lines (e.g., word lines) or access line groups (e.g., word line groups). Each deck may have one or more access line segments (e.g., word line segments). An access line segment may have fewer or more access lines than those in a deck. For example, a deck may have two word line segments distributed in one or more levels. In some cases, certain memory operations (e.g., an erase operation) can be performed to a word line group (e.g., a deck), and not to the entire memory block. By not performing an operation to the entire memory block, the particular operation may be performed faster.

FIG. 4A further illustrates that access lines 450, 451, 452, and 453 of memory device 130 can be located along (e.g., adjacent) respective portions (in the Z-direction) of pillar 441 in the same levels (e.g., levels 470, 471, 472, and 473, respectively) that memory cells 208₀, 208₁, 208₂, and 208₃ are located. Access lines can include, for examples, word lines or control gates. Access lines 450, 451, 452, and 453 can include (e.g., can be formed form) a conductive material (or materials). Example materials for access lines 450, 451, 452, and 453 include metal, alloy, doped polysilicon, other conductive materials.

In FIG. 4A, a select line (e.g., drain select gate or SGD) 481 can have a length extending in the X-direction (e.g., perpendicular to the lengths (in the Y-direction) of data lines 401 and 402). The materials of select line 481 can include a conductive material (e.g., conductively doped polysilicon, metal, other conductive material). FIG. 4A shows an example where another select line (e.g., source select gate or SGS) 480 can have a structure (e.g., shape, material, or both) similar to (or the same as) that of select line 481. In some examples, select line 480 can have a structure (e.g., shape, material, or both) similar to (or the same as) that of each of access lines 450, 451, 452, and 453.

As shown in FIG. 4A, a transistor (e.g., source select transistor) 465 and a transistor (e.g., drain select transistor) 463 can be located along (e.g., adjacent) respective portions of pillar 441 in the Z-direction. Memory cells 208₀, 208₁, 208₂, and 208₃ of memory cell string 231 can be located along the portion of pillar 441 that is between transistors 465 and 463.

Memory cell string 231 can include materials 403, 404, and 405 formed between portion 444 of pillar 441 and a respective access line among access lines 450, 451, 452, and 453. Material 403 can also be formed between pillar 441 and each of select lines 480 and 481. Materials 403, 404, and 405 located at a particular memory cell (among memory cells 208₀, 208₁, 208₂, and 208₃) can be a part (e.g., a memory element) of that particular memory cell. As shown in FIG. 4A, the combination of materials 403, 404, and 405 of a memory cell (among memory cells 208₀, 208₁, 208₂, and 208₃) can be separated from (in the Z-direction) the combination of materials 403, 404, and 405 of another memory cell (among memory cells 208₀, 208₁, 208₂, and 208₃).

Material 403 can include a charge blocking material (or charge blocking materials), for example, a dielectric material (e.g., silicon nitride) that is capable of blocking a tunneling of a charge. Material 404 can include a charge storage material (or charge storage materials) that can provide a charge storage function to represent a value of information stored in memory cells 208₀, 208₁, 208₂, and 208₃. For example, material 404 can include polysilicon (e.g., conductively doped polysilicon), which can be either a p-type polysilicon or an n-type polysilicon. The polysilicon can be configured to operate as a floating gate (e.g., to store charge) in a memory cell (e.g., a memory cell 208₀, 208₁, 208₂, and 208₃) In another example, material 404 can include a dielectric material (e.g., silicon-nitride based material or other dielectric materials) that can trap charge in a memory cell (e.g., a memory cell 208₀, 208₁, 208₂, and 208₃). Material 405 can include a tunnel dielectric material (or tunnel dielectric materials), for example, silicon dioxide, that is capable of allowing tunneling of a charge (e.g., electrons).

As shown in FIG. 4A, memory device 130 can include circuitry 495 located (e.g., formed) under memory array 201 (e.g., located directly under memory cell string 231). Circuitry 495 can include circuit elements (e.g., transistors T) coupled to other circuit elements (e.g., coupled to data lines 401-402) of memory device 130. The circuit elements (e.g., transistors T) of circuitry 495 can be configured to perform part of a function of a memory device (e.g., memory device 130). For example, circuitry 495 can include decoder circuits, driver circuits, buffers (e.g., page buffers), sense amplifiers, charge pumps, and other circuitry of memory device 130. In an alternative structure of memory device 130, circuitry 495 can be located (e.g., formed) above memory array 201 (instead of under memory array 201). For example, in the alternative structure of memory device 130, circuitry 495 can be located above memory array 201 and under data lines 401 and 402, or located between data lines 401 and 402 of memory array 201 in the Z-direction. In another example, in the alternative structure of memory device 130, circuitry 495 can be located above memory array 201 and above data lines 401 and 402 in the Z-direction.

A different view of pillar 441 along a cross-sectional line 4B-4B is shown in FIG. 4B. FIG. 4B shows a top view (e.g., a cross section with respect to the X-Y plan) of portion 444 of pillar 441 along line 4B-4B of FIG. 4A. As shown in FIG. 4B, portion 444 of pillar 441 can include material 444A and material 444B surrounded by material 444A. Material 444A can be (or can include) a part of a conductive structure (e.g., a conductive channel) of pillar 441. Material 444B can include a dielectric material. In an alternative structure of pillar 441, material 444B can be omitted from pillar 441, such that the entire portion 444 of pillar 441 can include material 444A (without material 444B).

FIG. 5 is a block diagram of a memory device in which an auto calibrated read operation and efficient program verification in an array of memory cells can be implemented in accordance with examples as disclosed herein. Memory device 500 (e.g., the memory device 130 of FIG. 1C) comprises micro-controller 502 (e.g., the local controller 135 of FIG. 1C), voltage generators 504, word line drivers 506, page buffers 508A-D, any array of memory cells 510 (e.g., the array of memory cells 104 of FIG. 1C, which can be an array of NAND memory cells), and a programming pulse generator comprising address circuitry 512 (e.g., the row decode circuitry 108 and column decode circuitry 111 of FIG. 1C) and a level shifter 514. Memory device 500 may also include strobe enabling circuitry (e.g., a part of the micro-controller 502 or a different circuitry not shown in FIG. 5) providing a strobe enable signal STRB_enable_0 516 corresponding to a first set of page buffers 508A and 508B (e.g., one or more of page buffer 152 of FIG. 1C) and bit lines (e.g., BL0 518A and BL1 518B) at a near-end 530 of a selected word line (with respect to the word line drivers 506), and a strobe enable signal STRB_enable_1 520 corresponding to a second set of page buffers 508C and 508D (e.g., one or more of page buffer 152 of FIG. 1C) and bit lines (e.g., bit lines BL8190 518C and BL8191 518D), at a far-end 540 of a selected word line (with respect to the word line drivers 506), and interface circuits 550.

A memory device 500 may include memory cells for storing a plurality of bits. The memory cells may be arranged in a two-dimensional grid. Memory cells are formed on a Silicon wafer in an array of columns and rows. As described above, memory cells in a column may be connected by a bit line and memory cells in a row may be connected by a word line. In one example, a memory device may include respective access line/word line driver circuitry 506 and voltage generators 504 for each plane of the memory device to facilitate concurrent access to pages of two or more memory planes including different page types. A memory block in a flash memory device may comprise an array of memory cells connected by word lines and bit lines such that data may be programmed or read from the flash memory device page-by-page. In a single-level cell (SLC) block of flash memory. every word line corresponds to one page. In a multi-level cell (MLC) block of flash memory, every word line corresponds to two pages. In a triple-level cell (TLC) block of flash memory, every word line corresponds to three pages. In a quad-level cell (QLC) of flash memory, every word line corresponds to four pages. In some cases, pages within a word line can be further interleaved such that each word line may correspond to additional pages.

A cell (e.g., a NAND cell of NAND memory cell array 510) of a block can store data in the form of a threshold voltage, which is a lowest voltage at which the cell can be activated (i.e., switched on). During a read operation of a cell (i.e. a “read cell”), a read reference voltage (V_{ref}) can be applied to an associated word line, and a sense amplifier connected to an associated bit line can be used to sense whether the read cell has been switched on.

With reference to both FIGS. 1A and 5, memory system 110 may be coupled with host system 105 via at least one physical host interface comprising interface circuits 550.

Page buffers 508A-D can further include sensing devices such as a sense amplifier, to sense a data state of a memory cell of the array of memory cells 510, e.g., by sensing a state of a data line (e.g., bit lines 518A-518D) connected to that memory cell. A status register (not shown) can be in communication with I/O control circuitry (e.g., I/O control circuitry 112) and/or a local memory controller (e.g., controller 135) to latch the status information for output to micro-controller 502.

A programming pulse generator may comprise address circuitry 512 and a level shifter 514. Address circuitry 512 receives block address signals to enable addressing different blocks of memory cell array 510. Level shifter 514 enables shifting block address signals between levels of a multiple-level memory cell (e.g., different levels of a quad-level memory cell) to address a particular level of a block of the array of memory cells 510.

With reference still to FIG. 5, strobe enabling circuitry may provide: STRB_enable_0 516 corresponding to page buffers, e.g., 508A and 508B and bit lines, e.g., BL0 518A and BL1 518B, at a near-end 530 of a selected word line (with respect to the word line drivers 506); and STRB_enable_1 520 corresponding to page buffers, e.g., page buffers 508C and 508D and bit lines, e.g., bit lines BL8190 518C and BL8191 518D, at a far-end 540 of a selected word line (with respect to the word line drivers 506). For example, in a program verify operation, a selected word line may be ramped linearly in a read operation, e.g., from −1V to 6V, while page buffers connected to corresponding memory cells of the word line enable strobe signals (e.g., signals 516 and/or 520) to detect if a threshold voltage, Vₜ, is higher than a program verify voltage on the word line at a given time when a strobe signal is applied. The number of strobe signals applied depends on the read algorithm being employed. In a quad-level memory cell, fifteen (15) strobes are required to verify all fifteen (15) program states (from L1 to L15).

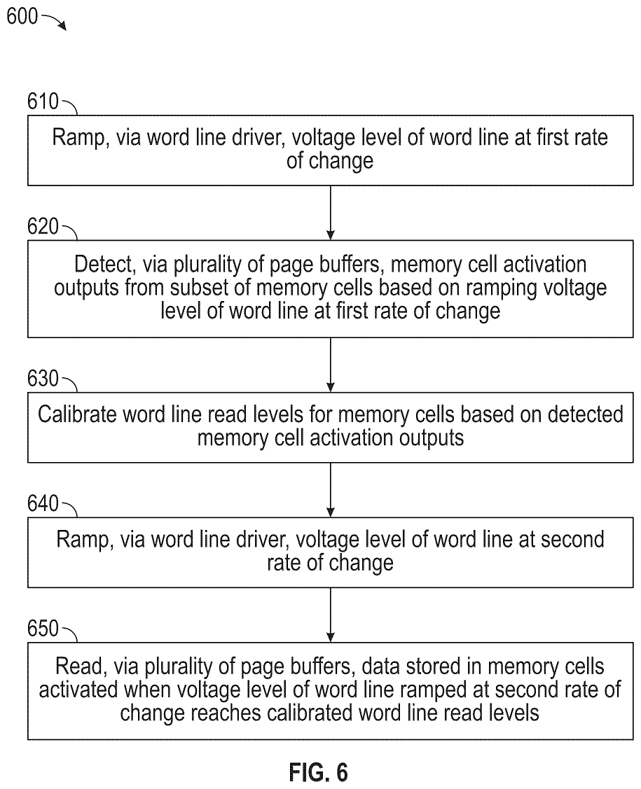

FIG. 6 illustrates a flowchart showing a process 600 that supports techniques for an auto calibrated read operation in an array of memory cells in accordance with examples as disclosed herein. For example, a flash memory device, e.g., device 500, may comprise an array of memory cells, e.g., an array of NAND memory cells 510, connected to a word line. A word line driver, e.g., any one of word line drivers 506, may be connected to the word line. The word line driver causes a voltage level of the word line to ramp up. In some embodiments, the word line driver may comprise a bit counter or voltage generator to generate digital progressive values, and a digital to analog converter (DAC) to convert the digital progressive values into an analog ramp signal operable to linearly ramp the voltage level, e.g., by applying N-step voltage pulses at each ramp step of the word line. A plurality of page buffers, e.g., page buffers 508A-508D, may be connected to respective ones of the memory cells via the bit lines 518A-518D. The plurality of page buffers detects memory cell activation outputs from the memory cells. A controller, e.g., micro-controller 502, may be connected to, and control, the word line driver(s) and the plurality of page buffers. The controller may have a memory storing software instructions which, when executed, cause the controller to perform one or more operations of process 600.

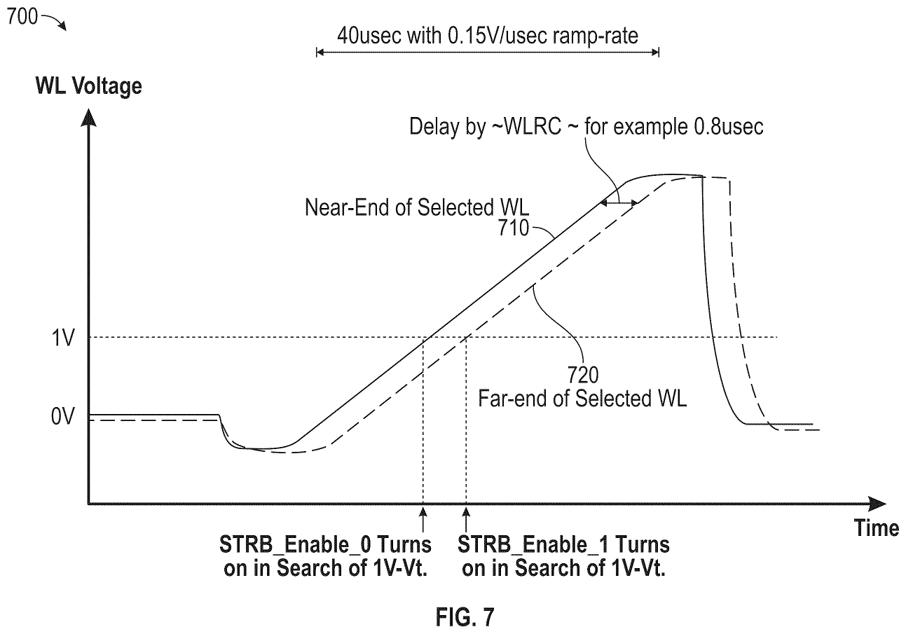

At block 610, the controller is caused to ramp, via a word line driver, a voltage level of the word line at a first rate of change. FIG. 7 is a graph 700 showing different curves that represent a comparison of word line waveforms during example read/program operations in accordance with examples as disclosed herein. For example, a controller connected to a word line driver and a plurality of page buffers, may have a memory storing software instructions which, when executed, cause the controller to perform one or more operations to ramp, via the word line driver, a voltage level of the word line at a first rate of change, e.g., about +0.15V/μs over 40 μs, as shown.

Referring back to FIG. 6 at block 620, the controller is further caused to detect, via a plurality of page buffers, memory cell activation outputs from a subset of memory cells in an array of memory cells based on ramping the voltage level of the word line at the first rate of change. For example, the controller may execute an operation to detect a threshold voltage distribution for a word line, i.e., a “Get-Vt-Distribution” operation, which may be carried out while a word line voltage is ramped up linearly, e.g., at a relatively quick ramping rate of 0.30V/μsec.

As shown in FIG. 5, a subset of memory cells may be located proximate to a near end of the word line with respect to the word line driver, and may comprise one of the following percentages of memory cells in an array of memory cells: about 50% of the memory cells, about 25% of the memory cells, or about 10% of the memory cells. The memory cell activation outputs may be detected via a subset of the plurality of page buffers. For example, the controller may enable one or more strobe signals, e.g., via STRB_enable_0516, for a subset of near-end page buffers (e.g., page buffers 508A and 508B) to detect the memory cell activation outputs. For example, the memory cells may comprise quad-level memory cells, and the controller may enable fifteen strobe signals to detect the memory cell activation outputs. Referring back to FIG. 7, there is an observed delay, e.g., of about 0.8 μs, between the application of a ramped word line voltage 710 at memory cells located proximate to a near end of a word line with respect to a word line driver and the change of the same ramped word line voltage 720 at memory cells located at a far end of the word line with respect to the word line driver. As shown in FIG. 7, when applying a particular word line voltage (e.g., 1V) at the near end, the particular word line voltage propagates to the far end after certain time delay (e.g., 0.8 μs). The time delay depends on the time constant of the word line (e.g., RC constant). The memory cell activation outputs may be detected via a subset of the plurality of page buffers, e.g., by enabling one or more strobe signals to detect the memory cell activation outputs. However, the strobe signal detection is delayed for the memory cells located at the far end of the word line because the strobe signal is enabled at a time depending on where the memory cell is located, i.e., the strobe signal is enabled later at the farther end.

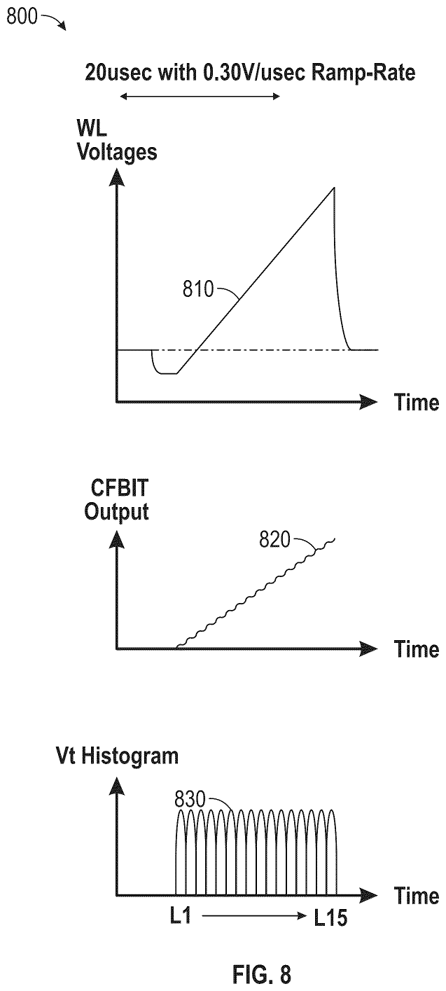

FIG. 8 is a graph 800 showing different curves that represent a first rate of change of the word line voltage level 810. memory cell activation outputs 820, and a threshold voltage distribution histogram 830 for an array of memory cells in accordance with examples as disclosed herein. For example, a controller (e.g., micro-controller 502) connected to a word line driver (e.g., one of drivers 506) and a plurality of page buffers (e.g., page buffers 508A-508D), may have a memory storing software instructions which, when executed, cause the controller to perform one or more operations to ramp, via the word line driver, a voltage level of the word line (e.g., one of word lines WL0-WL63 in FIG. 5) at a first rate of change. For example, the first rate of change of the word line voltage level 810 may be about +0.30V/us over 20 μs, as shown, but other ramp rates/time periods are possible. The controller is further caused to detect, via the plurality of page buffers, memory cell activation outputs 820 from a subset of the memory cells based on ramping the voltage level of the word line at the first rate of change. In an embodiment, the subset of memory cells may be located proximate to a near end of the word line with respect to the word line driver. The memory cell activation outputs 820 may be detected via a subset of the plurality of page buffers, e.g., by enabling one or more strobe signals to detect the memory cell activation outputs. The controller may be further caused to calibrate word line read levels for the memory cells based on the detected memory cell activation outputs 820. For example, a count fail bit (CFBIT) circuit may be connected to the plurality of page buffers. The CFBIT circuit can count a number of detected memory cell activation outputs 820, where a threshold voltage distribution may be calculated, e.g., as shown in V, histogram 830, based on the number of detected memory cell activation outputs 820.

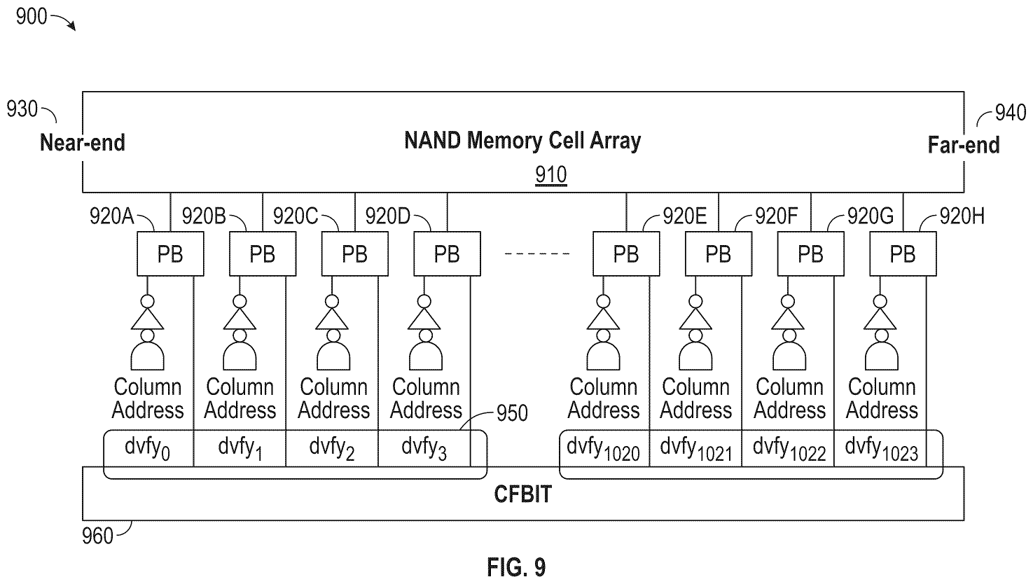

Referring back to FIG. 6, at block 630, the controller is further caused to calibrate word line read levels for the memory cells based on the detected memory cell activation outputs. FIG. 9 illustrates an example apparatus 900 for obtaining a threshold voltage distribution in an array of memory cells 910 in accordance with examples as disclosed herein. For example, a controller may be caused to detect memory cell activation outputs via a plurality of page buffers 920A-920D corresponding to near-end memory cells and page buffers 920E-920H corresponding to far-end memory cells 940. For example, page buffers 920A-920D may correspond to a subset of memory cells located proximate to a near end of the word line with respect to the word line driver. In an embodiment, the memory cell activation outputs 950 from page buffers 920A-920D corresponding to the subset of near-end memory cells located proximate to the near end of the word line may be used for calibration. For example, the subset of near-end memory cells may comprise one of the following: about 50% of the memory cells, about 25% of the memory cells, or about 10% of the memory cells. The memory cell activation outputs 950 may be detected via page buffers 920A-D, e.g., by enabling one or more strobe signals to detect the memory cell activation outputs 950. In an embodiment, a controller may be caused to calibrate word line read levels for the memory cells based on the detected memory cell activation outputs 950. For example, a count fail bit (CFBIT) circuit 960 may be connected to the plurality of page buffers 920A-H, the CFBIT circuit 960 to count a number of detected memory cell activation outputs 950, where a threshold voltage distribution used for calibration may be calculated based on the number of detected memory cell activation outputs 950.

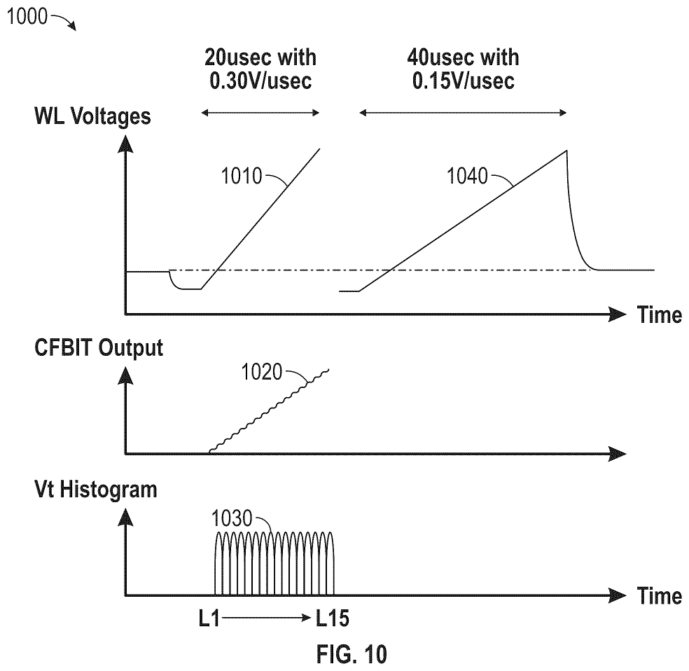

Referring back to FIG. 6 at block 640, the controller is further caused to ramp, via the word line driver, the voltage level of the word line at a second rate of change, and read (block 650), via the plurality of page buffers, data stored in the memory cells activated when the voltage level of the word line ramped at the second rate of change reaches the calibrated word line read levels. As described above, in block 630, the controller has caused to calibrate the word line read levels for the memory cells based on the detected memory cell activation outputs. Therefore, in block 640, the controller can use these calibrated word line read levels to perform the read operation while the voltage level of the word line ramps at the second rate of change (which may be slower than the first rate of change). The overall operation is therefore more efficient. FIG. 10 is a graph 1000 showing different curves that represent a first rate of change of the word line voltage level 1010. memory cell activation outputs 1020. a threshold voltage distribution histogram 1030, and a second rate of change of the word line voltage level 1040 for an auto calibrated read operation in an array of memory cells in accordance with examples as disclosed herein. For example, a controller (e.g., controller 502) connected to a word line driver (e.g., one of drivers 506) and a plurality of page buffers (e.g., page buffers 508), may have a memory storing software instructions which, when executed, cause the controller to perform one or more operations to ramp, via the word line driver, a voltage level of the word line at a first rate of change 1010. For example, the first rate of change of the word line voltage level 1010 may be a ramp up at about +0.30V/us over 20 μs, as shown, but other ramp rates/time periods are possible. The controller is further caused to detect, via the plurality of page buffers, memory cell activation outputs 1020 from a subset of the memory cells based on ramping the voltage level of the word line at the first rate of change. In an embodiment, the subset of memory cells may be located proximate to a near end of the word line with respect to the word line driver. For example, the subset of memory cells may comprise one of the following: about 50% of the memory cells, about 25% of the memory cells, or about 10% of the memory cells.

The memory cell activation outputs 1020 may be detected via a subset of the plurality of page buffers, e.g., by enabling one or more strobe signals to detect the memory cell activation outputs. The controller may be further caused to calibrate word line read levels for the memory cells based on the detected memory cell activation outputs 1020. For example, a count fail bit (CFBIT) circuit may be connected to the plurality of page buffers, the CFBIT circuit to count a number of detected memory cell activation outputs 1020, where a threshold voltage distribution may be calculated, e.g., as shown in Vₜ histogram 1030, based on the number of detected memory cell activation outputs 1020. The controller may be caused to ramp, via the word line driver, the voltage level of the word line at a second rate of change 1040, and read, via the plurality of page buffers, data stored in the memory cells activated when the voltage level of the word line ramped at the second rate of change 1040 reaches the calibrated word line read levels.

In some embodiments, the first rate of change of the word line voltage level 1010 may be different from the second rate of change of the word line voltage level 1040. For example, the first rate of change of the word line voltage level 1010 may be greater than the second rate of change of the word line voltage level 1040, or about twice the second rate of change of the voltage level. For example, the first rate of change of the word line voltage level 1010 may be about +0.30V/μs, while the second rate of change of the word line voltage level 1040 may be about +0.15V/μs. Thus, the word line voltage level 1010 at the first rate of change may be ramped/changed from a lower voltage level to a higher voltage level, e.g., +0.30V/μs, similar to the positive ramping of the word line voltage level at the second rate of change 1040, but more rapidly.

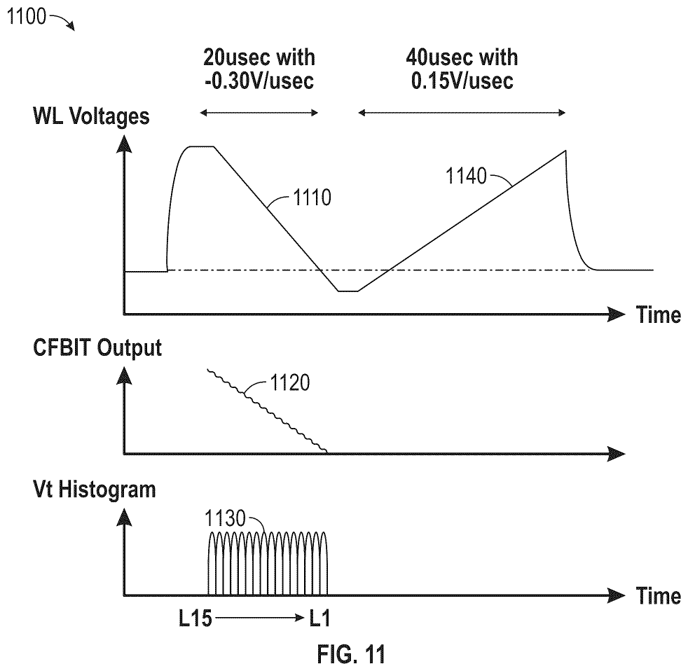

FIG. 11 is a graph 1100 showing different curves that represent a first rate of change of the word line voltage level 1110, memory cell activation outputs 1120. a threshold voltage distribution histogram 1130, and a second rate of change of the word line voltage level 1140 for an auto calibrated read operation in an array of memory cells in accordance with examples as disclosed herein. For example, a controller (e.g., micro-controller 502) connected to a word line driver (e.g., one of drivers 506) and a plurality of page buffers (e.g., page buffers 508), may have a memory storing software instructions which, when executed, cause the controller to perform one or more operations to ramp, via the word line driver, a voltage level of the word line at a first rate of change 1110. For example, the first rate of change of the word line voltage level 1110 may be a ramp down at about −0.30V/us over 20 μs, as shown, but other ramp rates/time periods are possible. The controller is further caused to detect, via the plurality of page buffers, memory cell activation outputs 1120 from a subset of the memory cells based on ramping the voltage level of the word line at the first rate of change. In an embodiment, the subset of memory cells may be located proximate to a near end of the word line with respect to the word line driver. For example, the subset of memory cells may comprise one of the following: about 50% of the memory cells, about 25% of the memory cells, or about 10% of the memory cells.

The memory cell activation outputs 1120 may be detected via a subset of the plurality of page buffers, e.g., by enabling one or more strobe signals to detect the memory cell activation outputs. The controller may be further caused to calibrate word line read levels for the memory cells based on the detected memory cell activation outputs 1120. For example, a count fail bit (CFBIT) circuit may be connected to the plurality of page buffers, the CFBIT circuit to count a number of detected memory cell activation outputs 1120, where a threshold voltage distribution may be calculated, e.g., as shown in Vₜ histogram 1130, based on the number of detected memory cell activation outputs 1120. The controller may be caused to ramp, via the word line driver, the voltage level of the word line at a second rate of change 1140, and read, via the plurality of page buffers, data stored in the memory cells activated when the voltage level of the word line ramped at the second rate of change 1140 reaches the calibrated word line read levels.

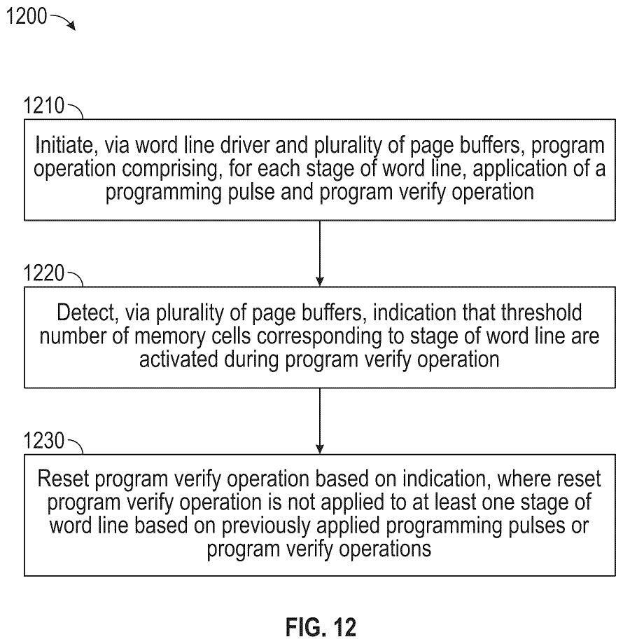

As shown in FIG. 11, in some embodiments, the first rate of change of the word line voltage level 1110 may be different from the second rate of change of the word line voltage level 1140. For example, the absolute value of the first rate of change of the word line voltage level 1110 may be greater than the second rate of change of the word line voltage level 1140, or about twice the second rate of change of the voltage level. For example, the absolute value of the first rate of change of the word line voltage level 1110 may be a ramp down at about −0.30V/μs, while the second rate of change of the word line voltage level 1140 may be a ramp up at about +0.15V/μs. For simplicity, regardless of whether the absolute value is used, the first rate of change may be compared to the second rate of change based on the number, and not the signs. Thus, the word line voltage level at the first rate of change 1110 may be changed from a higher voltage level to a lower voltage level, e.g., a ramp down at about −0.30V/μs, while the second rate of change of the voltage level may be a ramp up at about +0.15V/μs. Thus, the read or program verify operation can be based on a slower rate of change for the word line voltage level while the calibration can be a performed on a higher rate of change. FIGS. 12-15 below describe different stages of a program verify operation when the word line voltage level reaches different values.

In an embodiment, an efficient program verify operation can be initiated for each stage of a word line based on a CFBIT result. The efficiency can be provided at least by resetting a program verify operation based on if a threshold number of memory cells are activated. For example, a program verify operation may be reset based on an indication that a threshold number of the memory cells corresponding to a stage of the word line are activated. Each stage of a word line can be associated with a different group of memory cells connected to the word line. When the reset program verify operation is reset, it is not applied to memory cells corresponding to at least one stage of the word line based on previously applied programming pulses or program verify operations. Not applying the reset program verify operation to memory cells corresponding to at least one stage of the word line may comprise not applying the reset program verify operation memory cells corresponding to to a stage of the word line for which a program verify operation has been previously applied. The process is described in greater detail below.

FIG. 12 illustrates a flowchart showing a process that supports techniques for efficient program verification in an array of memory cells in accordance with examples as disclosed herein. For example, a flash memory device, e.g., device 500, may comprise memory cells, e.g., an array of NAND memory cells 510, connected to a word line partitioned into stages. In some embodiments, the number of stages of the word line may be based on a number a memory cell levels, where the memory cells comprise tri-level memory cells or quad-level memory cells. A word line driver, e.g., one of word line drivers 506, may be connected to the word line. The word line driver is configured to linearly change a voltage level of the word line over a period of time (e.g., ramp a voltage level of the word line). In some embodiments, the word line driver may comprise a bit counter or voltage generator to generate digital progressive values, and a digital to analog converter (DAC) to convert the digital progressive values into an analog ramp signal operable to linearly ramp the voltage level, e.g., by applying N-step voltage pulses at each ramp step of the word line. A plurality of page buffers, e.g., page buffers 508A-508D, may be connected to respective ones of the memory cells. The plurality of page buffers is configured to detect activation outputs from the memory cells. A controller, e.g., micro-controller 502, may be connected to the word line driver(s) and the plurality of page buffers. The controller may have a memory storing software instructions which, when executed, cause the controller to perform one or more operations of process 1200.

At block 1210, the controller is caused to initiate a program operation comprising an application of a programming pulse and a program verify operation for memory cells corresponding to each stage of a word line. At block 1220, the controller is further caused to detect, via the plurality of page buffers, that a threshold number of the memory cells corresponding to a stage of the word line are activated during the program verify operation. The indication may be based on activation outputs detected from the memory cells. For example, the controller may determine that the program verify operation for a stage of the word line is complete based on the indication that the threshold number of the memory cells corresponding to the stage of the word line are activated. The controller may then initiate a word line voltage level recovery operation based on the indication.

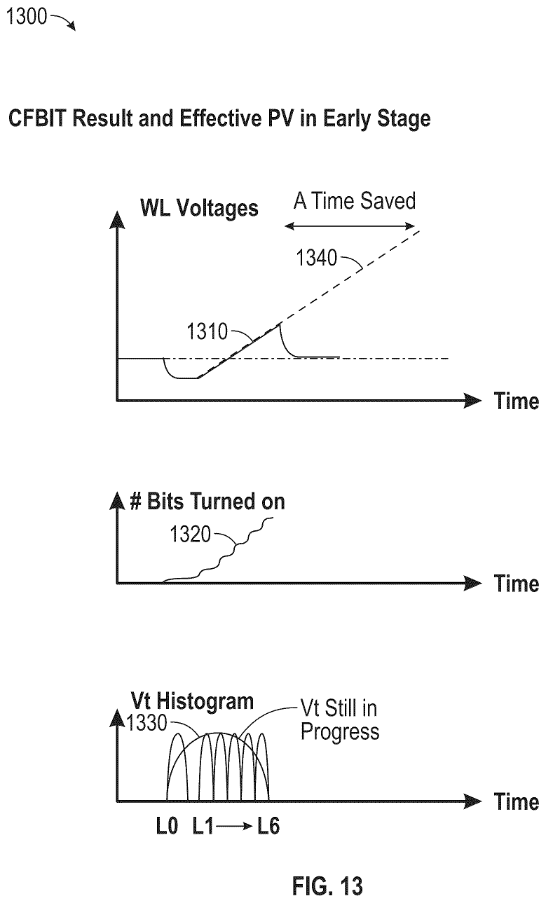

FIGS. 13-15 are graphs showing threshold voltage distribution (Vₜ) histograms (obtained using the CFBIT outputs) indicating that a threshold number of memory cells corresponding to each stage (e.g., early, middle, and later stages) of a word line are activated. For example, the controller may initiate a word line voltage level recovery operation based on such an indication at each stage of the word line during a program verify operation.

FIG. 13 is a graph 1300 showing different curves that represent a program pulse word line voltage 1310, a CFBIT output 1320, and a threshold voltage distribution (Vₜ) histogram 1330 for an array of memory cells in which an early stage of an efficient program verification is performed in accordance with examples as disclosed herein. In the early stage of a program verify operation, a program pulse word line voltage 1310 is low enough to avoid over-programming of lower-level program states. In this example, the CFBIT output 1320 of the number of bits turned-on and the Vₜ histogram 1330 (which is obtained using the CFBIT output 1320) show that the highest Vₜ in progress has reached L6 while the lowest Vₜ in progress is at L0. Since Vₜ in progress distributes from L0 to L6, program verify operations on L7-L15 word line voltages 1340 are not necessary at this stage.

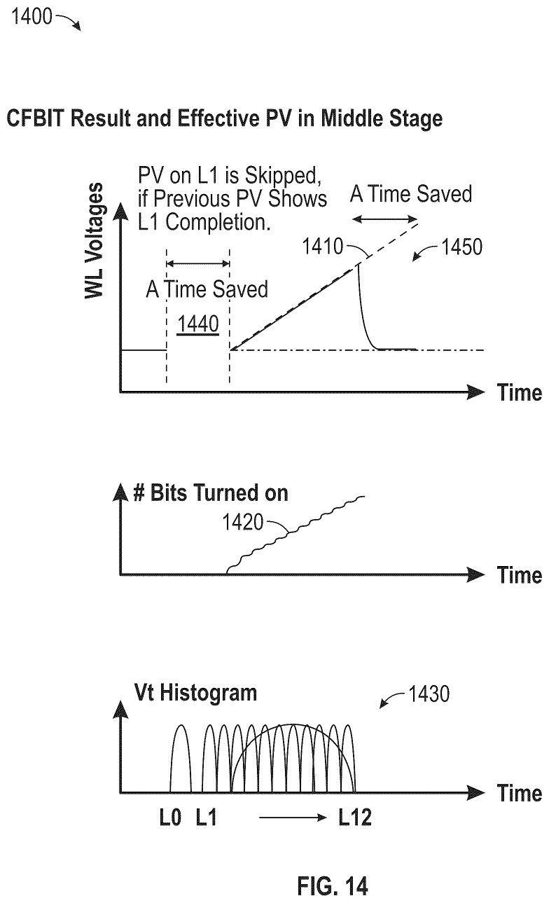

FIG. 14 is a graph 1400 showing different curves that represent a program pulse word line voltage 1410, a CFBIT output 1420, and a threshold voltage distribution histogram 1430 for an array of memory cells in which the middle stage of an efficient program verification is performed in accordance with examples as disclosed herein. In the middle stage of a program verify operation, a program pulse word line voltage 1410 is high enough to program middle-level program states. In this example, the CFBIT output 1420 of the number of bits turned-on and the Vₜ histogram 1430 show that the lowest Vₜ in progress has reached L3 while the highest Vₜ in progress is at L12. Since Vₜ in progress distributes from L3 to L12, program verify operations on L0-L2 word line voltages 1440 and L13-15 word line voltages 1450 are not necessary at this stage.

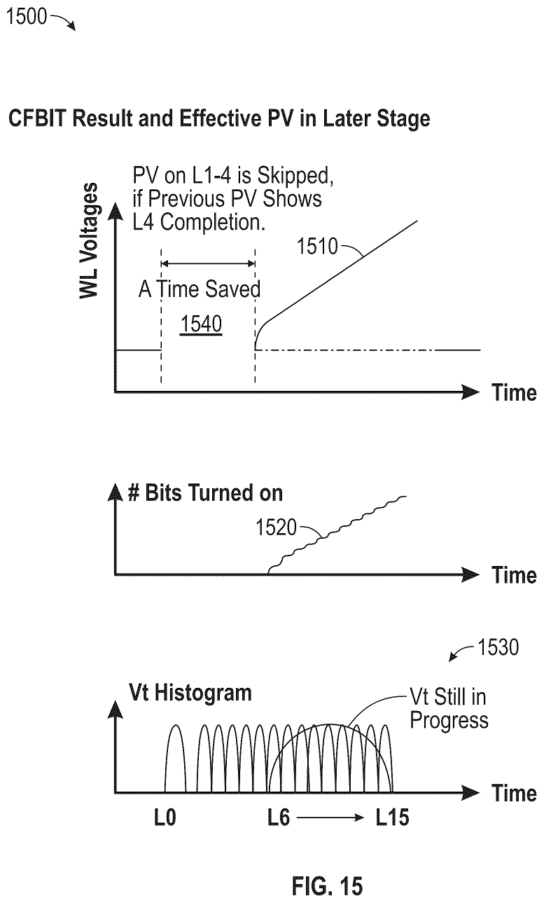

FIG. 15 is a graph 1500 showing different curves that represent a program pulse word line voltage 1510, a CFBIT output 1520, and a threshold voltage distribution histogram 1530 for an array of memory cells in which a later stage of an efficient program verification is performed in accordance with examples as disclosed herein. In the later stage of a program verify operation, a program pulse word line voltage 1510 is high enough to program higher-level program states. In this example, the CFBIT output 1520 of the number of bits turned-on and the Vₜ histogram 1530 show that the lowest Vₜ in progress has reached L6 while the highest Vₜ in progress is at L15. Since Vₜ in progress distributes from L6 to L15, program verify operations on L0-L5 word line voltages 1540 are not necessary at this stage. Thus, to perform efficient program verification, the process can be separated multiple stages (e.g., early, middle, later). In each stage, only certain Vₜ levels are verified.

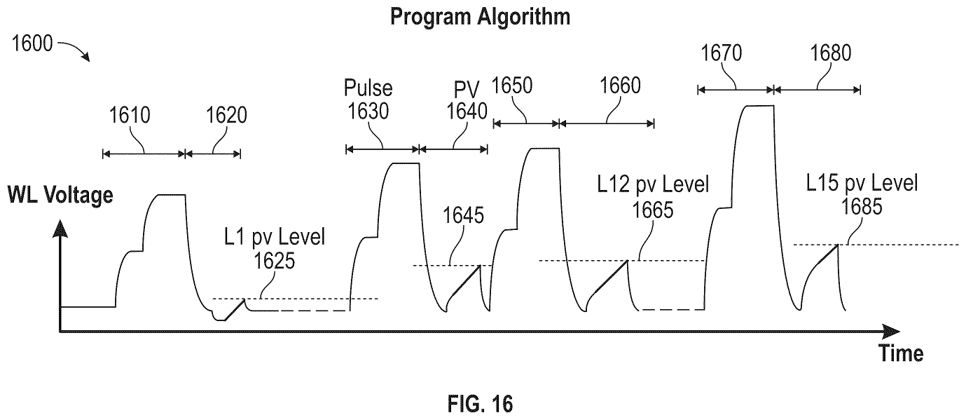

FIG. 16 is a graph 1600 showing a program algorithm 1600 for efficient program verification in an array of memory cells in accordance with examples as disclosed herein. A program operation of a memory device comprises a programming phase and a verification phase. The programming phase includes repeating the application of an incremental-step program pulse to a word line connected to memory cells, while the verification (program verify) phase includes verifying the program states of the memory cells. In a typical operation, the program operation can be terminated cell-by-cell based on which memory cells have been successfully programmed (based on bit-by-bit program verification). As the number of bits per memory cell increases, a programming time can increase due to the increase in the number of program states per cell and smaller program pulse steps. Single-level memory cells have just two states with, e.g., a 1V-step pulse, while quad-level memory cells have sixteen (16) states with, e.g., 0.25V-step pulses. In quad-level memory cells, the time required to verify each of the program levels becomes dominant with respect to overall programming time.

In a program verify operation, a selected word line is ramped linearly, e.g., from −1V to 6V, while page buffers connected to corresponding memory cells of the word line enable strobe signals to detect if a threshold voltage, Vₜ, is higher than a program verify voltage on the word line at a given time when a strobe signal is applied. The number of strobe signals applied depends on the read algorithm being employed. In a quad-level memory cell, fifteen (15) strobes are required to verify all fifteen (15) program states (from L1 to L15).

In an initial (early) stage of an efficient program verify operation in accordance with embodiments herein, a program pulse 1610 is low enough to avoid over-programming of lower-level program states. In this example, the highest Vₜ in progress has reached L1 while the lowest Vₜ in progress is at L0. Since Vₜ in progress distributes from L0 to L1, program verify operations 1620 are enabled up to an L1 program verify word line voltage level 1625. Higher program verify word line voltage levels, e.g., L2-15, are not necessary at this stage.

In a middle stage of a program verify operation in accordance with the embodiments herein, a program pulse 1630 is high enough to program some middle-level program states. In this example, the highest Vₜ in progress has reached L6 while the lowest Vₜ in progress is at L2. Since Vₜ in progress distributes from L2 to L6, program verify operations 1640 are enabled on L2-6 word line voltages levels 1645. Lower program verify word line voltage levels, L0-L1, and higher program verify word line voltage levels, L7-15, are not necessary at this stage.

In a next middle stage of a program verify operation, a program pulse 1650 is high enough to program additional middle-level program states. In this example, the lowest Vₜ in progress has reached L7 while the highest Vₜ in progress is at L12. Since Vₜ in progress distributes from L7 to L12, program verify operations 1560 are enabled on L7-L12 word line voltages levels 1665. Lower program verify word line voltage levels, L0-L6, and higher program verify word line voltage levels, L13-L15, are not necessary at this stage.

In the later stage of a program verify operation, a program pulse 1670 is high enough to program higher-level program states. In this example, the lowest Vₜ in progress has reached L13 while the highest Vₜ in progress is at L15. Since Vₜ in progress distributes from L13 to L15, program verify operations 1680 are enabled on L13-L15 word line voltage levels 1685. Lower program verify word line voltage levels, L0-L12, are not necessary at this stage.

Referring back to FIG. 12 at block 1230, the controller is further caused to reset the program verify operation based on the indication, where the reset program verify operation is not applied to memory cells corresponding to at least one stage of the word line based on previously applied programming pulses or program verify operations. For example, not applying the reset program verify operation to memory cells corresponding to at least one stage of the word line may comprise not applying the reset program verify operation to memory cells corresponding to a stage of the word line for which a program verify operation has been previously applied. In some embodiments, the stage of the word line for which the program verify operation has been previously applied may be determined based on a threshold number of bits detected in the stage of the word line during a program verify operation. In another example, not applying the reset program verify operation to memory cells corresponding to at least one stage of the word line may comprise not applying the reset program verify operation to memory cells corresponding to a stage of the word line for which a programming pulse has not yet been applied.

At each stage, a count fail bit (CFBIT) circuit is connected to a plurality of page buffers to count a number of bits that have turned on during a program verify operation. Each page buffer outputs a bit-information ‘1’ that indicates when an associated memory cell has turned on. The CFBIT circuit also detects Ln (n=1-15) program completion. Each page buffer outputs a bit-information ‘2’ that indicates when an associated memory cell has reached a designated program verify level. Thus, the CFBIT circuit counts a number of bits corresponding to a number of activation outputs from the memory cells; and provides an indication when the number of bits detected reaches a threshold number of bits. In an embodiment, word line voltage levels can be enabled to go to a recovery state earlier when the CFBIT circuit indicates that all memory cells have turned on during a program verify operation. For example, a tolerance value may be applied to confirm the threshold number of bits, or the threshold number of bits may comprise a maximum number of bits for a stage of the word line.

Additional embodiments are included below.
(1) A memory device comprising:
   memory cells connected to a word line;
   a word line driver connected to the word line, the word line driver being configured to ramp a voltage level of the word line;
   a plurality of page buffers connected to respective ones of the memory cells, the plurality of page buffers being configured to detect memory cell activation outputs from the memory cells, and
   a controller connected to the word line driver and the plurality of page buffers, the controller having a memory storing software instructions which, when executed, cause the controller to perform one or more operations to: ramp, via the word line driver, a voltage level of the word line at a first rate of change;
      detect, via the plurality of page buffers, memory cell activation outputs from a subset of the memory cells based on ramping the voltage level of the word line at the first rate of change;
      calibrate word line read levels for the memory cells based on the detected memory cell activation outputs;
      ramp, via the word line driver, the voltage level of the word line at a second rate of change; and
      read, via the plurality of page buffers, data stored in the memory cells activated when the voltage level of the word line ramped at the second rate of change reaches the calibrated word line read levels.
(2) The device of (1), wherein the controller is further caused to:
   calculate a threshold voltage distribution based on the detected memory cell activation outputs; and
   calibrate the read level of the word line based on the threshold voltage distribution.
(3) The device of (2), further comprising:
   a count fail bit (CFBIT) circuit connected to the plurality of page buffers, the CFBIT circuit being configured to count a number of detected memory cell activation outputs, wherein the controller is operable to calculate the threshold voltage distribution based on the number of detected memory cell activation outputs.
(4) The device of any of (1)-(3), wherein the subset of memory cells is located proximate to a near end of the word line with respect to the word line driver.
(5) The device of (4), wherein the subset of memory cells comprises one of the following: about 50% of the memory cells, about 25% of the memory cells, or about 10% of the memory cells.
(6) The device of any of (1)-(5), wherein the first rate of change of the voltage level is different from the second rate of change of the voltage level.
(7) The device of any of (1)-(6), wherein the first rate of change of the voltage level is greater than the second rate of change of the voltage level.
(8) The device of any of (1)-(7), wherein the first rate of change of the voltage level is about twice the second rate of change of the voltage level.
(9) The device of any of (1)-(8), wherein the controller is further caused to change the voltage level at the first rate of change from a lower voltage level to a higher voltage level.
(10) The device of (9), wherein the first rate of change of the voltage level is about +0.30V/us.
(11) The device of any of (1)-(10), wherein the controller is further caused to change the voltage level at the first rate of change from a higher voltage level to a lower voltage level.
(12) The device of (11), wherein the first rate of change of the voltage level is about −0.30V/μs.
(13) The device of any of (1)-(12), wherein the second rate of change of the voltage level is about +0.15V/μs.
(14) The device of any of (1)-(13), wherein the memory cell activation outputs are detected via a subset of the plurality of page buffers.
(15) The device of any of (1)-(14), wherein the controller is further caused to enable, via the plurality of page buffers, one or more strobe signals to detect the memory cell activation outputs.
(16) The device of any of (1)-(15), wherein the memory cells comprise quad-level memory cells.
(17) The device of (16), wherein the controller is further caused to enable, via the plurality of page buffers, fifteen strobe signals to detect the memory cell activation outputs.
(18) The device of any of (1)-(17), wherein the word line driver comprises:
   a bit counter or voltage generator to generate digital progressive values; and
   a digital to analog converter (DAC) to convert the digital progressive values into an analog ramp signal operable to linearly ramp the voltage level of the word line.
(19) A method of performing a read operation for memory cells connected to a word line in a flash memory device, the method comprising:
   ramping, via a word line driver, a voltage level of the word line at a first rate of change;
   detecting, via a plurality of page buffers, memory cell activation outputs from a subset of the memory cells based on ramping the voltage level of the word line at the first rate of change;
   calibrating word line read levels for the memory cells based on the detected memory cell activation outputs;
   ramping, via the word line driver, the voltage level of the word line at a second rate of change; and
   reading, via the plurality of page buffers, data stored in the memory cells activated when the voltage level of the word line ramped at the second rate of change reaches the calibrated word line read levels.
(20) A method of manufacturing a flash memory device, the method comprising:
   connecting memory cells to a word line;
   connecting a word line driver to the word line, the word line driver to ramp a voltage level of the word line;
   connecting a plurality of page buffers to respective ones of the memory cells, the plurality of page buffers to detect memory cell activation outputs from the memory cells; and
   connecting a controller to the word line driver and the plurality of page buffers, the controller having a memory storing software instructions which, when executed, cause the controller to perform one or more operations comprising:
      ramping, via the word line driver, a voltage level of the word line at a first rate of change;
      detecting, via the plurality of page buffers, memory cell activation outputs from a subset of the memory cells based on ramping the voltage level of the word line at the first rate of change;
      calibrating word line read levels for the memory cells based on the detected memory cell activation outputs;
      ramping, via the word line driver, the voltage level of the word line at a second rate of change; and
      reading, via the plurality of page buffers, data stored in the memory cells activated when the voltage level of the word line ramped at the second rate of change reaches the calibrated word line read levels.
(21) A memory device comprising:
   memory cells connected to a word line partitioned into stages;
   a word line driver connected to the word line, the word line driver to linearly change a voltage level of the word line over a period of time;
   a plurality of page buffers connected to respective ones of the memory cells, the plurality of page buffers to detect activation outputs from the memory cells; and
   a controller connected to the word line driver and the plurality of page buffers, the controller having a memory storing software instructions which, when executed, cause the controller to perform one or more operations to:
      initiate, via the word line driver and the plurality of page buffers, a program operation comprising, for memory cells corresponding to each stage of the word line, an application of a programming pulse and a program verify operation;
      detect, via the plurality of page buffers, an indication that a threshold number of the memory cells corresponding to a stage of the word line are activated during the program verify operation; and
      reset the program verify operation based on the indication, wherein the reset program verify operation is not applied to memory cells corresponding to at least one stage of the word line based on previously applied programming pulses or program verify operations.
(22) The device of (21), wherein the controller is further caused to:
determine that the program verify operation for a stage of the word line is completed based on the indication that the threshold number of the memory cells corresponding to the stage of the word line are activated.

The device of any of (21)-(22), wherein the indication is based on activation outputs detected from the memory cells.
(24) The device of any of (21)-(23), wherein the controller is further caused to: initiate, via the word line driver, a word line voltage level recovery operation based on the indication.
(25) The device of any of (21)-(24), wherein not applying the reset program verify operation to at least one stage of the word line comprises not applying the reset program verify operation to a stage of the word line for which a program verify operation has been previously applied.
(26) The device of (25), wherein the controller is further caused to determine the stage of the word line for which the program verify operation has been previously applied based on a threshold number of bits detected in the stage of the word line during a program verify operation.
(27) The device of any of (21)-(26), wherein not applying the reset program verify operation to at least one stage of the word line comprises not applying the reset program verify operation to a stage of the word line for which a programming pulse has not yet been applied.
(28) The device of any of (21)-(27), further comprising:
   a count fail bit (CFBIT) circuit connected to the plurality of page buffers, the CFBIT
      circuit to:
         count a number of bits corresponding to a number of activation outputs from the memory cells; and
         provide the indication when the number of bits detected reaches a threshold number of bits.
(29) The device of (28), wherein the controller is further caused to apply a tolerance value to confirm the threshold number of bits.
(30) The device of any of (28)-(29), wherein the threshold number of bits comprises a maximum number of bits for a stage of the word line.
(31) The device of any of (21)-(30), wherein a number of stages of the word line is based on a number a memory cell levels.
(32) The device of any of (21)-(31), wherein the memory cells comprise tri-level memory cells.
(33) The device of any of (21)-(32), wherein the memory cells comprise quad-level memory cells.
(34) A method of performing a program operation for memory cells connected to a word line partitioned into stages in a memory device, the method comprising:
   initiating, via a word line driver and a plurality of page buffers, a program operation comprising, for memory cells corresponding to each stage of the word line, an application of a programming pulse and a program verify operation;
   detecting, via the plurality of page buffers, an indication that a threshold number of the memory cells corresponding to a stage of the word line are activated during the program verify operation; and
   resetting the program verify operation based on the indication, wherein the reset program verify operation is not applied to memory cells corresponding to at least one stage of the word line based on previously applied programming pulses or program verify operations.
(35) A method of manufacturing a memory device, the method comprising:
   connecting memory cells to a word line partitioned into stages;
   connecting a word line driver to the word line, wherein the word line driver is operable to linearly change a voltage level of the word line over a period of time;
   connecting a plurality of page buffers to respective memory cells, the plurality of page buffers to detect activation outputs from the memory cells; and
   connecting a controller to the word line driver and the plurality of page buffers, the controller having a memory storing software instructions which, when executed, cause the controller to perform, one or more operations comprising:
      initiating, via a word line driver and a plurality of page buffers, a program operation comprising, for memory cells corresponding to each stage of the word line, an application of a programming pulse and a program verify operation;
      detecting, via the plurality of page buffers, an indication that a threshold number of the memory cells corresponding to a stage of the word line are activated during the program verify operation; and
      resetting the program verify operation based on the indication, wherein the reset program verify operation is not applied to memory cells corresponding to at least one stage of the word line based on previously applied programming pulses or program verify operations.

It should be noted that the described techniques include possible implementations, and that the operations and the blocks may be rearranged, reordered, or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily doped, e.g., degenerate, semiconductor region. The source and drain may be separated by a lightly doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device comprising:
memory cells connected to a word line;
a word line driver connected to the word line, the word line driver being configured to ramp a voltage level of the word line;
a plurality of page buffers connected to respective ones of the memory cells, the plurality of page buffers being configured to detect memory cell activation outputs from the memory cells, and
a controller connected to the word line driver and the plurality of page buffers, the controller having a memory storing software instructions which, when executed, cause the controller to perform one or more operations to:
ramp, via the word line driver, a voltage level of the word line at a first rate of change;
detect, via the plurality of page buffers, memory cell activation outputs from a subset of the memory cells based on ramping the voltage level of the word line at the first rate of change;
calibrate word line read levels for the memory cells based on the detected memory cell activation outputs;
ramp, via the word line driver, the voltage level of the word line at a second rate of change; and
read, via the plurality of page buffers, data stored in the memory cells activated when the voltage level of the word line ramped at the second rate of change reaches the calibrated word line read levels.

2. The device of claim 1, wherein the controller is further caused to:
calculate a threshold voltage distribution based on the detected memory cell activation outputs; and
calibrate the read level of the word line based on the threshold voltage distribution.

3. The device of claim 2, further comprising:
a count fail bit (CFBIT) circuit connected to the plurality of page buffers, the CFBIT circuit being configured to count a number of detected memory cell activation outputs, wherein the controller is operable to calculate the threshold voltage distribution based on the number of detected memory cell activation outputs.

4. The device of claim 1, wherein the subset of memory cells is located proximate to a near end of the word line with respect to the word line driver.

5. The device of claim 1, wherein the first rate of change of the voltage level is different from the second rate of change of the voltage level.

6. The device of claim 1, wherein the controller is further caused to change the voltage level at the first rate of change from a lower voltage level to a higher voltage level.

7. The device of claim 1, wherein the controller is further caused to change the voltage level at the first rate of change from a higher voltage level to a lower voltage level.

8. The device of claim 1, wherein the second rate of change of the voltage level is about +0.15V/μs.

9. The device of claim 1, wherein the memory cell activation outputs are detected via a subset of the plurality of page buffers.

10. The device of claim 1, wherein the controller is further caused to enable, via the plurality of page buffers, one or more strobe signals to detect the memory cell activation outputs.

11. The device of claim 1, wherein the memory cells comprise quad-level memory cells.

12. The device of claim 11, wherein the controller is further caused to enable, via the plurality of page buffers, fifteen strobe signals to detect the memory cell activation outputs.

13. The device of claim 1, wherein the word line driver comprises:
a bit counter or voltage generator to generate digital progressive values; and
a digital to analog converter (DAC) to convert the digital progressive values into an analog ramp signal operable to linearly ramp the voltage level of the word line.

14. A memory device comprising:
memory cells connected to a word line partitioned into stages;
a word line driver connected to the word line, the word line driver to linearly change a voltage level of the word line over a period of time;
a plurality of page buffers connected to respective ones of the memory cells, the plurality of page buffers to detect activation outputs from the memory cells; and
a controller connected to the word line driver and the plurality of page buffers, the controller having a memory storing software instructions which, when executed, cause the controller to perform one or more operations to:
initiate, via the word line driver and the plurality of page buffers, a program operation comprising, for memory cells corresponding to each stage of the word line, an application of a programming pulse and a program verify operation;
detect, via the plurality of page buffers, an indication that a threshold number of the memory cells corresponding to a stage of the word line are activated during the program verify operation; and
reset the program verify operation based on the indication, wherein the reset program verify operation is not applied to memory cells corresponding to at least one stage of the word line based on previously applied programming pulses or program verify operations.

15. The device of claim 14, wherein the controller is further caused to:
determine that the program verify operation for a stage of the word line is completed based on the indication that the threshold number of the memory cells corresponding to the stage of the word line are activated.

16. The device of claim 14, wherein the indication is based on activation outputs detected from the memory cells.

17. The device of claim 14, wherein the controller is further caused to:
initiate, via the word line driver, a word line voltage level recovery operation based on the indication.

18. The device of claim 14, wherein not applying the reset program verify operation to at least one stage of the word line comprises not applying the reset program verify operation to a stage of the word line for which a program verify operation has been previously applied.

19. The device of claim 18, wherein the controller is further caused to determine the stage of the word line for which the program verify operation has been previously applied based on a threshold number of bits detected in the stage of the word line during a program verify operation.

20. The device of claim 14, wherein not applying the reset program verify operation to at least one stage of the word line comprises not applying the reset program verify operation to a stage of the word line for which a programming pulse has not yet been applied.

21. The device of claim 14, further comprising:
a count fail bit (CFBIT) circuit connected to the plurality of page buffers, the CFBIT circuit to:
count a number of bits corresponding to a number of activation outputs from the memory cells; and
provide the indication when the number of bits detected reaches a threshold number of bits.

22. The device of claim 21, wherein the controller is further caused to apply a tolerance value to confirm the threshold number of bits.

23. The device of claim 21, wherein the threshold number of bits comprises a maximum number of bits for a stage of the word line.
